(19) United States
(12) Patent Application Publication
(10) Pub. No.: US 2026/0297803 A1
(43) Pub. Date: Oct. 1, 2026

(54) Silicon Carbide Crystal Growth System

(71) Applicant: Wolfspeed, Inc., Durham, NC (US)

(72) Inventors: Brian Bennett Haidet, Raleigh, NC (US); Caleb Andrew Kent, Durham, NC (US); Steven Herbert Griffiths, Morrisville, NC (US)

(21) Appl. No.: 19/213,629

(22) Filed: May 20, 2025

Related U.S. Application Data
(60) Provisional application No. 63/779,905, filed on Mar. 28, 2025.

(51) Int. Cl. C30B 23/06; C23C 14/06; C23C 14/24; C30B 29/36

(52) U.S. Cl. CPC C30B 23/06; C23C 14/0635; C23C 14/243; C30B 29/36

(57) ABSTRACT

A silicon carbide crystal growth sublimation system is provided. The system comprises an outer enclosure, a crucible within the outer enclosure, and an outer chamber between the crucible and the outer enclosure. The system is configured such that during a sublimation process a pressure within the crucible is less than a pressure within the outer chamber.

### PRIORITY CLAIM

The present application claims the benefit of priority of U.S. Provisional Application Serial No. 63/779,905, filed on Mar. 28, 2025, which is incorporated herein by reference.

### FIELD

The present disclosure relates generally to crystal growth systems, such as silicon carbide crystal growth systems for growing crystalline silicon carbide semiconductor workpieces for fabrication of semiconductor devices.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”) and other devices. Example semiconductor devices may be diodes, such as Schottky diodes or other devices.

Power semiconductor devices may be packaged into various semiconductor device packages, such as discrete semiconductor device packages and power modules. Power modules may include one or more power devices and other circuit components and can be used, for instance, to dynamically switch large amounts of power through various components, such as motors, inverters, generators, and the like.

Semiconductor devices may be fabricated from wide bandgap semiconductor materials, such as silicon carbide and/or Group III nitride-based semiconductor materials. The fabrication process for power semiconductor devices may require processing of wide bandgap semiconductor wafers, such as silicon carbide semiconductor wafers.

Single crystal silicon carbide (SiC) has proven to be a very useful wafer material in the manufacture of such semiconductor devices. Due to its physical strength and excellent resistance to many chemicals, SiC may be used to fabricate very robust substrates adapted for use in the semiconductor industry. SiC has excellent electrical properties, including radiation hardness, high breakdown field, a relatively wide band gap, high saturated electron drift velocity, high-temperature operation, and absorption and emission of high-energy photons in the blue, violet, and ultraviolet regions of the optical spectrum.

SiC crystalline material may be produced using various seeded sublimation growth processes. In a typical SiC growth process, a seed material and source material are arranged in a reaction crucible which is then heated to the sublimation temperature of the source material. By controlled heating of the environment surrounding the reaction crucible, a thermal gradient is developed between the sublimating source material and the marginally cooler seed material. By means of the thermal gradient, source material in a vapor phase is transported onto the seed material where it condenses to grow a bulk crystalline boule. This type of crystalline growth process is commonly referred to as physical vapor transport (PVT) process.

A resulting SiC boule may then be sliced using into wafers, and the individual wafers may then be used as seed material for a seeded sublimation growth process, or as substrates upon which a variety of semiconductor devices (e.g., power semiconductor devices and optical applications, such as LEDs, windows, photo-diodes, etc.) may be formed.

### SUMMARY

Aspects and advantages of embodiments of the present disclosure will be set forth in part in the following description, or can be learned from the description, or can be learned through practice of the embodiments.

In an aspect, the present disclosure provides an example silicon carbide crystal growth sublimation system. The system comprises an outer enclosure, a crucible within the outer enclosure, and an outer chamber between the crucible and the outer enclosure. The system is configured such that during a sublimation process a pressure within the crucible is less than a pressure within the outer chamber.

In another aspect, the present disclosure provides an example silicon carbide crystal growth sublimation system. The system comprises an outer enclosure, a crucible within the outer enclosure, and an outer chamber between the crucible and the outer enclosure. The crucible comprises one or more walls comprising graphite and having a nitrogen gas permeability of 10⁻¹⁶ m² or less.

In another aspect, the present disclosure provides an example silicon carbide crystal growth sublimation system. The system comprises an outer enclosure, a crucible within the outer enclosure, and an outer chamber between the crucible and the outer enclosure. The system is configured such that during a sublimation process the outer chamber is essentially free of silicon-containing vapor.

In another aspect, the present disclosure provides an example silicon carbide crystal growth sublimation apparatus. The apparatus comprises an outer enclosure, a crucible within the outer enclosure, an outer chamber between the crucible and the outer enclosure, and a barrel comprising graphite at least partially surrounding the crucible and between the crucible and the outer enclosure.

In another aspect, the present disclosure provides an example method of growing a single-crystal of silicon carbide (SiC crystal) using a physical vapor transport (PVT) process in a sublimation system. The method comprises placing a source material containing silicon carbide in a reaction crucible and heating the sublimation system to a temperature of at least 1800°C. The sublimation system comprises an outer enclosure, a crucible within the outer enclosure, and an outer chamber between the crucible and the outer enclosure. A pressure within the crucible is less than a pressure within the outer chamber.

In another aspect, the present disclosure provides an example silicon carbide crystal growth sublimation system. The system comprises an outer enclosure, a crucible within the outer enclosure, an outer chamber between the crucible and the outer enclosure, a first pumping system fluidly connected to a crystal growth chamber within the crucible, and a second pumping system fluidly connected to the outer chamber.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a crystal growth system according to example aspects of the present disclosure.

FIG. 2 depicts a crystal growth system according to example aspects of the present disclosure.

FIG. 3 depicts a crystal growth system according to example aspects of the present disclosure.

FIG. 4 depicts a crystal growth system according to example aspects of the present disclosure.

FIG. 5 depicts a crystal growth system according to example aspects of the present disclosure.

FIG. 6 depicts a crystal growth system according to example aspects of the present disclosure.

FIG. 7 depicts a crystal growth system according to example aspects of the present disclosure.

FIG. 8 depicts a crystal growth system according to example aspects of the present disclosure.

FIG. 9 depicts a crystal growth system according to example aspects of the present disclosure.

FIGS. 10A-10C depict crystal growth systems according to example aspects of the present disclosure.

FIG. 11 depicts a crystal growth system according to example aspects of the present disclosure.

FIG. 12 depicts a crystal growth system according to example aspects of the present disclosure.

FIG. 13 depicts a crystal growth system according to example aspects of the present disclosure.

FIG. 14 depicts a crystal growth system according to example aspects of the present disclosure.

FIG. 15 depicts a crystal growth system according to example aspects of the present disclosure.

FIG. 16 depicts a crystal growth system according to example aspects of the present disclosure.

FIG. 17 depicts a crystal growth system according to example aspects of the present disclosure.

FIG. 18 depicts a flow chart of an example method according to example embodiments of the present disclosure.

Repeat use of reference characters in the present specification and drawings is intended to represent the same and/or analogous features or elements of the present invention.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

In silicon carbide crystal growth systems, a reaction crucible may be placed inside an outer enclosure (e.g., metal “can”), resulting in a crystal growth chamber inside the crucible and an outer chamber outside the crucible and within the outer enclosure. The outer chamber typically contains insulation material and heating elements. The absolute gas pressures inside and outside the crucible are controlled by multiple diffusive, flow, and phase-change factors. The outer chamber is supplied with a mixture of inert gases, which is pumped down to a specified pressure, maintaining a particular stoichiometry of “inert” species (e.g., argon). This gas can stochastically diffuse through the crucible walls, where it meets sublimated Si₂C, SiC₂, and Si species. The total pressure of these sublimated species is higher than the pressure outside the crucible, but the small pore size of the crucible walls allows inert gas to diffuse in stochastically, against the pressure gradient.

As the total pressure inside the crucible is larger than the pressure in the outer chamber, any orifices large enough to support pressure-driven flow (rather than diffusive flow) act as leak paths, lowering the crucible pressure and venting the contents of the crucible into the outer chamber. This leaking of sublimated species (e.g., silicon vapor) from the higher pressure crystal growth chamber to the lower pressure outer chamber can significantly damage insulation components and heating coils, resulting in short lifetimes of such components.

In some cases, the pressure in the outer chamber is chosen to balance the two competing factors of hot zone component (e.g., insulation and heating coils) lifetime and crystal growth rate. For example, high pressures reduce evaporation from hot surfaces, so at high pressure, hot zone insulation materials and heater coils have longer lifetimes. Low pressures, conversely, enhance sublimation and diffusion of gaseous species. Therefore, low pressures inside the crucible are beneficial for fast transport of source material to the seed crystal. While typical crystal growth processes have found a balance between growth rate and system lifetime, if the pressure in the outer chamber could be increased without increasing the pressure in the crucible, higher crystal growth rates and longer component lifetimes could be achieved.

In this regard, example aspects of the present disclosure are directed to crystal growth systems (e.g., silicon carbide crystal growth systems) with different pressure zones, particularly in which the pressure inside the crucible is less than the pressure of the outer chamber.

In some embodiments, a dual-pump system may be employed, where separate pressure control systems exist for the crystal growth chamber and the outer chamber. For maximum control, both the outer chamber and the crucible may have independent gas inlets and pumps and can be completely isolated from each other. Such a system can be leveraged to extend the life of grower components, increase crystal growth rate via new convection mechanisms, enable new geometries for longer growth programs, and grant direct control over doping species injection. For example, in some embodiments, by using a pump attached to the crucible outlet any leaked species can travel through a gas trap and out of the enclosure. The pressure inside the crucible can be kept low regardless of the pressure in the outer chamber, and the deleterious species can be contained, increasing grower component lifetime.

In some embodiments, a double-barrel scheme is used to contain the crucible inlet gas. In this configuration, the crucible inlet and outlet can be built into a rotary feedthrough at the top of the grower. Gas for doping (e.g., N₂) can be flowed into the space between the outer and inner barrels, where it can diffuse into the crucible and incorporate into the crystal. The outer barrel can be impermeable to gases but capable of reradiating heat from the coil inwards.

In some embodiments, the impermeable outer barrel can be attached directly to the chamber lid. In this configuration, the outer barrel can be static with respect to the heating coils, and the crucible (i.e., inner barrel) can move within its own controlled pressure zone. This method can simplify pumping/feedthrough connections.

In some embodiments, the crucible outlet can have its own pump, but the crucible can receive gas input from the outer chamber. In such embodiments, the permeability of the crucible walls can be carefully selected for doping control. The high-pressure gas in the outer chamber can still diffuse into the crucible, and with careful control of crucible wall permeability, flow constrictions around the crystal, and pumping rate, the pressure in the crucible could remain relatively low.

In some embodiments, the crucible walls can be made more impermeable to diffusive flow than typical systems, but no pumps or gas inlets are added. As such, pressure-driven flow past the crystal can dominate, and the pressure in the outer chamber can be increased relative to typical systems but remain below the combined vapor pressure of SiC species in the crucible without causing a decrease in growth rate.

The systems described herein can provide numerous technical effects, benefits, and advantages, including cost-reduction and capacity-enhancement. If typical coil temperature and crystal growth rate are maintained but with higher pressure in the outer chamber, then insulation and coil lifetime can be increased (i.e., they will last for more crystal growth runs), and the impact of the costs of these components will be reduced on a per-wafer basis. If coil temperature is increased compared to typical systems but with higher pressure in the outer chamber, faster and/or taller SiC boules can be grown at matched component lifetime (i.e., the typical number of crystal growth runs), providing additional capacity-enhancing and cost-reducing effects.

In addition to improvements in component lifetime, an extra pumping circuit inside the crucible can allow for forced convection and faster motion of species throughout the crucible. For example, forced inert flow through the powder bed (i.e., the source) can provide faster sublimation and flow of species through deeper powder.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, n type material has a majority equilibrium concentration of negatively charged electrons, while p type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments and, although specific terms are employed, they are used in a generic and descriptive sense only and not for purposes of limitation of the scope set forth in the following claims.

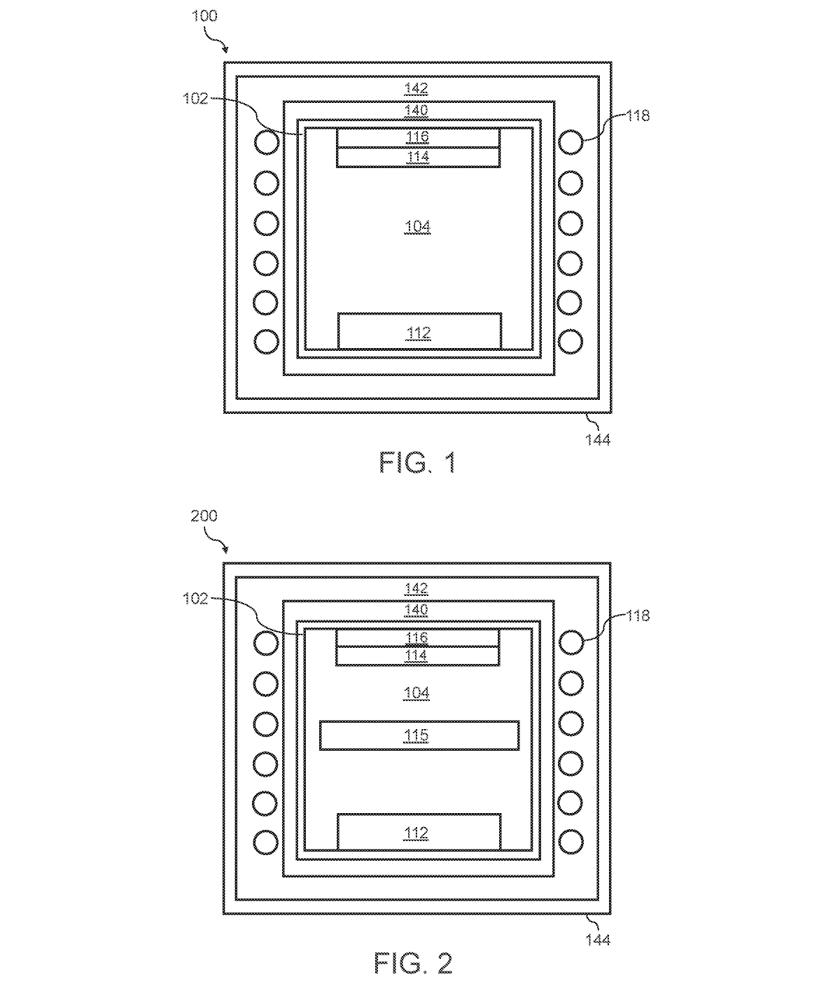

FIG. 1 is a simplified cross-sectional schematic diagram of a crystal growth system 100 adapted for use in a crystal growth process of the type contemplated by certain embodiments of the disclosure. The crystal growth system 100 includes a reaction crucible 102 (also referred to as a susceptor, growth cell, or inner barrel) and an outer enclosure 144 housing the reaction crucible 102. A heater 118 (e.g., heating coils) at least partially surrounds the reaction crucible 102 and is adapted to heat the reaction crucible 102 when electrical current is applied. The heater 118 may be a resistive heater and include one or more resistive heating coils. Using any competent heating mechanism and approach, the temperature within the outer enclosure 144 housing the reaction crucible 102 may be controllable. The reaction crucible 102 at least partially defines a crystal growth chamber 104. An outer chamber 142 exists between the reaction crucible 102 and the outer enclosure 144. The reaction crucible 102 may be, at least in part, a graphite structure. As explained in further detail below, the material forming the reaction crucible can be selected to have a desired level of permeability.

The outer enclosure 144 and the reaction crucible 102 may also include one or more gas inlet and gas outlet ports and associated equipment allowing the controlled introduction and evacuation of gas from the outer chamber 142 and/or the crystal growth chamber 104, as will be described in further detail below. The introduction and evacuation of various gases to/from the crystal growth chamber 104 and the outer chamber 142 may be accomplished using a variety of inlets/outlets, pipes, valves, pumps, gas sources, and controllers. In some embodiments, the outer enclosure 144 may be a metal structure.

Reaction crucible 102 may be surrounded by insulation material 140. The composition, size, and placement of insulation material 140 will vary with individual crystal growth systems in order to define and/or maintain desired thermal gradients (both axially and radially) in relation to reaction crucible 102. For purposes of clarity, the term, “thermal gradient,” will be used herein to describe one or more thermal gradient(s) associated with reaction crucible 102. Those skilled in the art recognize that “the thermal gradient” established in embodiments of the disclosure will contain (or may be further characterized as having) axial and radial gradients, or may be characterized by a plurality of isotherms.

A seed holder 116 may be configured to position the seed crystal 114 in the crystal growth chamber 104. The seed crystal 114 may have a 4H crystal structure, 6H crystal structure, or other crystal structure. The seed crystal 114 can be on-axis (e.g., end face parallel to the (0001) plane) or off-axis (e.g., end face non-parallel to the (0001) plane). Growth may occur on the silicon face or the carbon face of the seed crystal 114. A silicon carbide vapor source material 112 may be provided in the crystal growth chamber 104. During a crystal growth process, silicon carbide vapor or other vapor may be transported from the source material 112 to the seed crystal 114 to grow a crystalline material boule on the seed crystal 114. The source material 112 may be a powdered silicon carbide source material, solid silicon carbide source material, carbon and/or silicon source material, etc. Example silicon carbide source materials are disclosed in U.S. Application Serial No. 18/963,103, filed on Nov. 27, 2024 and in U.S. Application Serial No. 18/963,117, filed on Nov. 27, 2024, both of which are incorporated herein by reference.

For instance, in some examples, the silicon carbide source material includes a shaped solid silicon carbide source material structure. In some embodiments, the structure may have a composite shape. As used herein, “composite shape” and “composite shaped” refer to any three-dimensional object or component that deviates from a regular cylindrical shape, or a composite solid structure containing multiple shaped solids which may have simple or complex shapes. Deviations from a cylindrical shape include forms with regular or irregular geometries that do not conform to the typical circular or elliptical cross-section of a cylinder. Such structures may exhibit various shapes, including but not limited to structures with polygonal cross-sections; irregularly curved structures; and shapes with holes, voids, surface variations, or combinations thereof. The term also includes shapes containing multiple interconnected or distinct substructures. The substructures may themselves be composite shaped or may be cylindrically shaped. The term encompasses a wide range of geometric configurations and excludes objects that maintain a uniform cylindrical profile throughout their entire volume.

As used herein, “shaped solid” and “solid structure” refer to non-powdered solid components. A non-powdered component, for example, can have a size in at least one dimension of about 1 µm or greater, such as about 10 µm or greater, such as about 50 µm or greater, such as about 100 µm or greater, such as about 200 µm or greater, such as about 1000 µm or greater, such as about 1700 µm or greater, such as about 5 mm or greater, such as about 10 mm or greater. In some example embodiments, a shaped solid or solid structure may be formed by binding powdered particles together to form a composite material. Shaped solids may be shaped in an intentional manner to influence relevant properties, such as sublimation rate, vapor flow paths, thermal gradients, etc. Shaped solids may have one or more shape modifications. Shape modifications are intentional modifications to a source structure to influence relevant properties, such as sublimation rate, vapor flow paths, thermal gradients, etc.

In some embodiments, a composite shaped structure may include complex geometry including shapes, features, symmetry, asymmetry, dimensions, thicknesses, and/or appendages to improve such parameters. In some embodiments, the shaped solid source material may have features that provide desired thermal gradients within the source material. In some embodiments, the shaped solid source material may have features that provide high surface area for better sublimation rates. In some embodiments, the shaped solid source material may have features that provide desired gas flow paths through the source material to efficiently transport the sublimated SiC. In some embodiments, the shaped solid source material may have features that are tailored based on known local variations (e.g., temperature variations) within the crucible. In some embodiments, the shaped solid source material may have features that allow for directional control of the gas flow or heat flow within the source. In some embodiments, the shaped solid source material may have features that allow for control of the sublimation rate over time. Such features are described in more detail below with reference to the drawings.

The source material can be intentionally shaped to control the sublimation rate over time and thus during various stages of crystal growth. The source material can also be shaped to obtain a desired vapor flow/local vapor pressure relative to the seed/growing crystal surface.

In some embodiments, the silicon carbide source material structure may contain multiple layers varying in at least one property. For example, it may include an outer layer and an inner layer such that when used in a sublimation process, the outer layer sublimates first, followed by the inner layer. Varying the properties of the layers can affect the sublimation properties (e.g., rate, temperature required) and crystal growth properties (e.g., polytype, dopant concentration, defect concentration, shape, growth rate).

In some embodiments, the silicon carbide source material structure includes a dopant. The inclusion of a dopant in the source material provides a method for incorporating the dopant into the silicon carbide crystal. This is particularly useful for incorporating dopants which are not easily incorporated using a vapor source.

In some examples, the crystal growth system 100 may include one or more actuators. The actuators may be configured to impart translational and/or rotational movement to one or more components of the crystal growth system 100, such as the seed holder 116 and seed crystal 114, the source material 112, the heater 118, the reaction crucible 102 and/or other elements. The actuator(s) may be include any suitable type of actuator, such as an electric actuator (e.g., servo motor, stepper motor, linear motor, DC motor, AC motor, rotary motor), piezoelectric actuator, pneumatic actuator (e.g., pneumatic cylinder, pneumatic diaphragm), hydraulic actuator (e.g., hydraulic cylinder), electromagnetic actuator (e.g., solenoid), thermal actuator (e.g., shape memory alloy actuator, bimetallic actuator), vacuum actuator (e.g., vacuum suction actuator) and/or other suitable actuator, rotary actuator (e.g., screwing arrangement). The actuator(s) may be operated independently of each other to cause relative positioning of components relative to other components. Those of ordinary skill in the art, using the disclosure provided herein, will understand that any type of actuator may be used to move components without deviating from the scope of the present disclosure. The actuators may be used with any of the crystal growth systems provided herein.

In some embodiments, the pressure (i.e., absolute pressure) P₁ within the crystal growth chamber 104 is less than the pressure P₂ within the outer chamber 142. In some embodiments, the pressure difference (P₂-P₁) may be about 1 Torr or more, such as about 5 Torr or more, such as about 10 Torr or more, such as about 50 Torr or more, such as about 100 Torr or more, such as about 200 Torr or more, such as about 300 Torr or more, such as about 500 Torr or more. However, even a pressure difference of 0 can be an improvement over typical growth systems, which tend to have a higher pressure within the crystal growth chamber than in the outer chamber. By operating the crystal growth system 100 such that P₂ is more than P₁, the heater 118 and the insulation 140 may experience less evaporation/sublimation, providing them with longer lifetimes. Further, during the sublimation growth process, the outer chamber 142 may be essentially free of silicon containing vapor. This may be the result of the pressure differential preventing flow of vapors from the crystal growth chamber 104 to the outer chamber 142 and/or through the use of an impermeable structure (i.e., barrel or outer barrel) between the crystal growth chamber 104 and the outer chamber 142, as will be discussed in further detail below. As the presence of silicon vapor can damage insulation and heater material, preventing it from escaping into the outer chamber 142 can also contribute to increasing the lifetime of such components. As used herein, “essentially free” means that the concentration of a specified component (e.g., silicon) is present in an amount of about 1000 ppm or less, such as about 100 ppm or less, such as about 10 ppm or less, such as about 1 ppm or less, such as 0 ppm.

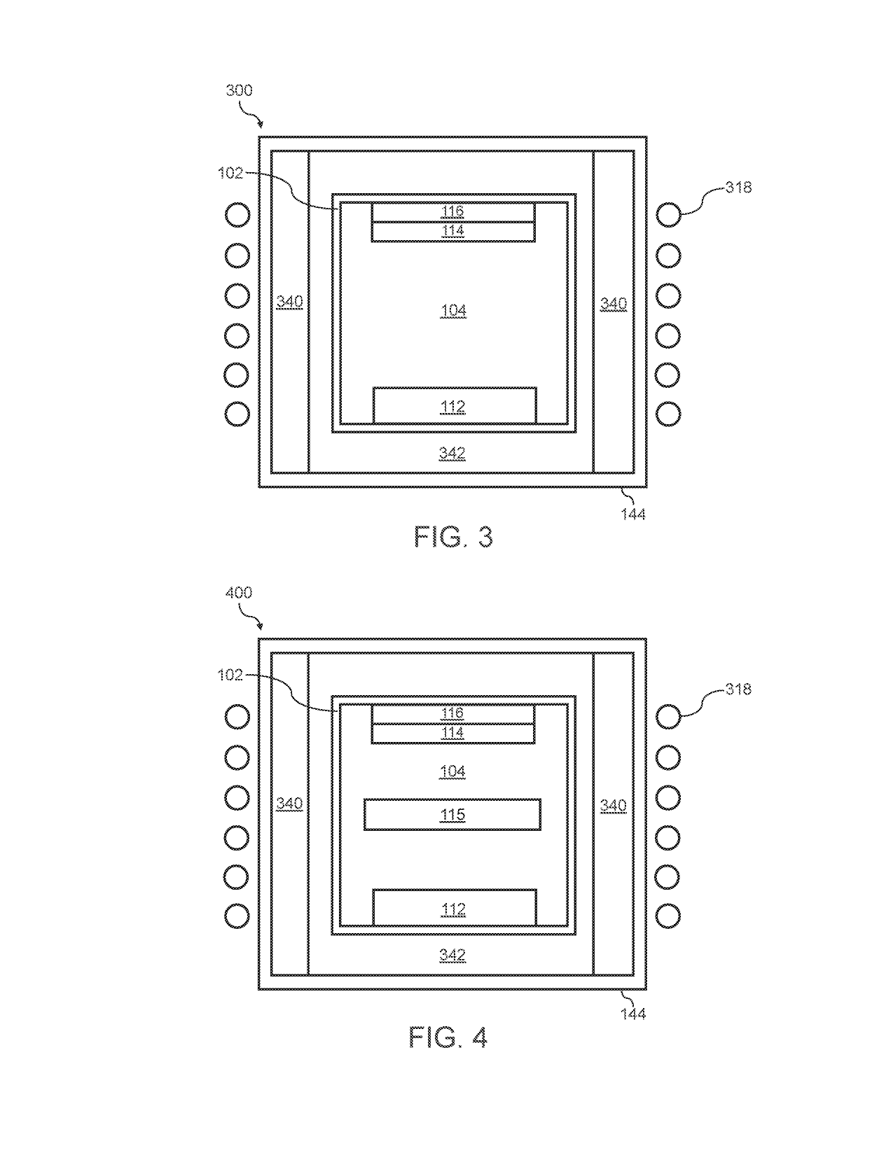

FIG. 2 is a simplified cross-sectional schematic diagram of a crystal growth system 200 adapted for use in a crystal growth process of the type contemplated by certain embodiments of the disclosure. Like the crystal growth system 100 of FIG. 1, the crystal growth system 200 of FIG. 2 includes the reaction crucible 102, the crystal growth chamber 104, the source material 112, the seed crystal 114, the seed holder 116, the heater 118, the insulation 140, the outer enclosure 144, and the outer chamber 142.

Crystal growth system 200 may additionally include an interface structure 115 within the crystal growth chamber 104. The interface structure may include one or more apertures and/or a porous material that allows the transport of vapor through the material. In some examples, the interface structure 115 may include a baffle structure or secondary source. Example baffle structures that may be used are disclosed in U.S. Patent Application No. 18/962,454, filed on Nov. 27th, 2024, which is incorporated herein by reference.

For instance, in some examples, the baffle structure includes a porous material, such as porous graphite. In some examples, at least a portion of the baffle structure has a porosity of greater than about 50% by volume, such as greater than about 70% by volume, such as greater than 80% by volume. Porosity by volume expressed as a percentage refers to the percentage of the volume of voids in the baffle relative to the total volume of the material. In some embodiments, the baffle has a porosity in a range of about 50% to about 97%, such as about 80% to about 97%, such as about 85% to about 97%.

In some embodiments, the baffle structure includes one or more apertures defined through a thickness of the baffle. As used herein, an “aperture” is a defined opening, space, perforation, hole, or void in a structure that extends from one exterior surface of a structure to another exterior surface of the structure. In some embodiments, the baffle has a long dimension that is generally non-perpendicular to the growth surface of the seed crystal. In some examples, the one or more apertures include a plurality of holes defined through the baffle. In some examples, the one or more apertures include an annular aperture defined through a thickness of the baffle. In some examples, a vapor transport direction through the one or more apertures is in a non-perpendicular direction relative to the growth surface of the seed crystal.

In some examples, the one or more apertures are arranged in the baffle to provide for non-uniform vapor transport from the source material to the seed crystal. In some examples, the one or more apertures are arranged in the baffle to provide for asymmetric vapor transport from the source material to the seed crystal. In some examples, the one or more apertures include a first aperture and a second aperture, wherein a width of the first aperture is different from a width of the second aperture. In some examples, the one or more apertures include a first plurality of apertures and a second plurality of apertures, wherein a density of the first plurality of apertures in the baffle is different from a density of the second plurality of apertures in the baffle.

In some examples, the baffle includes a plurality of dividers arranged in a non-perpendicular direction relative to the growth surface of the seed crystal. In some examples, the one or more apertures are arranged to direct vapor in a direction that is more towards a center of the seed crystal relative to a peripheral portion of the seed crystal. In some examples, the one or more apertures are arranged to direct vapor in a direction that is more towards a peripheral portion of the seed crystal relative to a central portion of the seed crystal.

In some examples, the baffle includes a plurality of baffle structures (e.g., baffle plates). In some examples, the baffle includes a first baffle plate having the one or more apertures and a second baffle plate with no apertures. In some examples, the baffle includes a first baffle plate comprising a first aperture and a second baffle plate comprising a second aperture. In some examples, the first aperture is aligned with the second aperture. In some examples, the first aperture is not aligned with the second aperture.

In some examples, one or more portions of the baffle element, coating, surface or subsurface treatment for the baffle or any of its parts may include an engineered structure having a construction or configuration that is or includes one or more of a porous structure, woven wire, perforated plate, foam, screen printed material, refractory metal, 3D printed structure, coated wire, carbon fiber mesh, carbon wires, refractory metal wires, woven mesh, cast component(s), grid, sintered powder, composite laminate, electroformed structure, braided wire, honeycomb structure, felt structure, nanostructured film, carbon nanotubes, tightly or loosely interconnected network of structures or other suitable construction or configuration. Portions or the entirety of any of the foregoing may be coated, treated and/or converted to form a metal carbide surface, subsurface or entire article of metal carbide. One or more combinations of any of these constructions or configurations may be used without deviating from the scope of the present disclosure. For example, in some embodiments, a first baffle structure (e.g., a first baffle plate) may include a first configuration (e.g., porous material) and a second baffle structure (e.g., a second baffle plate) may include a second configuration (e.g., honeycomb structure). In some examples, the baffle structure may be a secondary source or may comprise a secondary source, such as a secondary carbon source (e.g., if the interface structure comprises graphite).

In some examples, the interface structure 115 may be a graphite material (e.g., porous graphite, such as porous graphite having a porosity in a range of greater than about 40%, such as greater than about 70%, such as in a range of about 40% to about 97%, such as in a range of about 70% to about 97%). In some examples, the interface structure 115 may be a coated graphite material. Example coatings that may be used are disclosed in U.S. Application Serial No. 18/963,196, filed on Nov. 27, 2024, U.S. Application Serial No. 18/963,136, filed on Nov. 27, 2024, and U.S. Application Serial No. 18/963,240, filed on Nov.27, 2024, which are incorporated herein by reference.

In some embodiments, a coating may include metal particles and a binder that forms a matrix holding the particles together in a coating. In some embodiments, the metal may be tantalum. In some embodiments, the metal particles may be less than 10 microns in diameter. In some embodiments, the binder may be a thermally curable resin. In some embodiments, the metal particles may be functionalized with compounds that promote particle dispersion in the coating and may couple to the binder. In some embodiments, the coating is stable in air, forms a stable suspension, and can be used to dip-coat or paint parts. In some embodiments, solvent may be added to the coating, for example to tune the viscosity of the coating, tune the metal particle concentration, or tune the coating uniformity. In some embodiments, a compound that promotes sintering may be added to the coating mixture to promote sintering of the particles (e.g., at temperatures above 1000° C). The thickness of the final coating may be able to be controlled, for example by varying the concentration of metal particles in the coating and by varying the deposition volume of the coating onto the surface or part.

In some embodiments, a coating be created by applying an organometallic compound to at least one surface of a structure, wherein the at least one surface of the structure contains carbon or an oxide, curing the organometallic compound on the at least one surface of the structure; and heating the organometallic compound on the at least one surface of the structure such that the metal carbide coating is formed on the at least one surface of the structure, wherein the organometallic compound includes a central metal atom; and ligands capable of forming polydentate bonds to the central metal atom.

In some embodiments, the central metal atom is selected from the group consisting of chromium, hafnium, iridium, molybdenum, niobium, osmium, rhenium, rhodium, ruthenium, tantalum, titanium, tungsten, vanadium, zirconium, or a mixture thereof. In some embodiments, the central metal atom is tantalum. In some embodiments, the ligands capable of forming polydentate bonds to the central metal atom are polar. In some embodiments, the ligands capable of forming polydentate bonds to the central metal atom are selected from the group consisting of alkyl amines, alkyl acetates, alkyl alcohols, alkyl glycols, alkyl diols, alkyl nitrites, alkyl halides, alkyl aromatics, alkylated charge transfer donor-acceptor pairs, or a mixture thereof.

In some examples, furanic ultra high temperatures adhesives (UHTAs) may be used as a binder in a paint that converts to a coating, such as solution processable ceramic coatings (e.g., TaC, NbC, SiC, etc.) or a non-ceramic coating (e.g., glassy carbon coatings). Certain furan functionalized compound can be used as ultra-high temperature adhesives. The chemistry of furan rings allows a broad range of furan-containing polymeric, molecular, or inorganic-organic hybrid materials that can function as UHTAs. Examples of such materials incorporating the furan heterocycle as a structural unit include: furanic polymers and resins; furanic molecules and macromolecules; furanic rigid network solids; and furan functionalized micromaterials or nanomaterials.

With the proper material design, the furanic constituents would allow these compounds to participate in crosslinking (curing) through Diels-Alder cycloaddition and the formation of a bonded glassy carbon (BGC) network. Crosslinking, which forms a three-dimensional polymeric network, can be initiated through the application of chemical, photochemical, thermal, mechanical, or electrical energy. Once cured, these materials become structurally robust solids that bind strongly to a substrate. As these cured solids are pyrolized, the furan constituents undergo ring opening and forming reactive alkene fragments ( CH2=CH2 ) and radicals which drive the formation of and condensation of polyaromatic cores resulting in a BGC network, which results in an UHTA.

The adhesion of furanic UHTAs may be further improved through the incorporation of a filler material. Use of such filler materials with UHTAs as a binding agent may be referred to as a “brick and mortar” model. Such filler materials may improve the adhesive properties of the UHTA by mechanical reinforcement. During pyrolysis of the furanic UHTA, the filler or any products generated by the chemical change of the filler may be incorporated into the network as a structural unit and mechanically strengthen the resulting bonded glassy carbon network through covalent bonding and/or strong non-covalent interactions. Such filler materials may also improve the adhesive properties of the UHTA by promoting carbon condensation. During pyrolysis of the furanic UHTA, the filler or any products generated by the chemical change of the filler may aid in the condensation of intermediate polyaromatic cores through covalent bonding and/or strong non-covalent interactions. By contributing to the condensation, a denser bonded glassy carbon network may be produced.

In some embodiments, filler materials used with furanic UHTAs may be active or may be passive. Active fillers undergo a chemical change (e.g., thermal decomposition, reduction, oxidation, solid state synthesis, etc.) into one or more products during the pyrolysis of the UHTA. Active fillers may also change aggregate state or are subject to diffusion before or during undergoing a chemical change. Passive fillers can form covalent bonds or participate in strong non-covalent interactions with the bonded glassy carbon network, but do not undergo further chemical reactions during the pyrolysis of the UHTA. Passive fillers can be impermeable or can be porous, allowing the furanic UHTA to penetrate into the material. In the case of a porous filler, the bonded glassy carbon network may form inside and outside the filler material during the pyrolysis of the UHTA. Passive fillers may participate in sintering, recrystallization, surface or bulk diffusion processes during temperature exposure. Either active or passive fillers may also create voids or porosity during temperature treatments. For example, fillers may decompose or evaporate to create voids in the UHTA.

The interface structure 115 may extend all the way across a width or diameter of the growth chamber. The interface structure 115 may be used in any of the crystal growth systems provided herein without deviating from the scope of the present disclosure.

Similar to the crystal growth system 100 shown in FIG. 1, the pressure P₁ within the crystal growth chamber 104 is less than the pressure P₂ within the outer chamber 142. Further, during the sublimation growth process, the outer chamber 142 may be essentially free of silicon containing vapor.

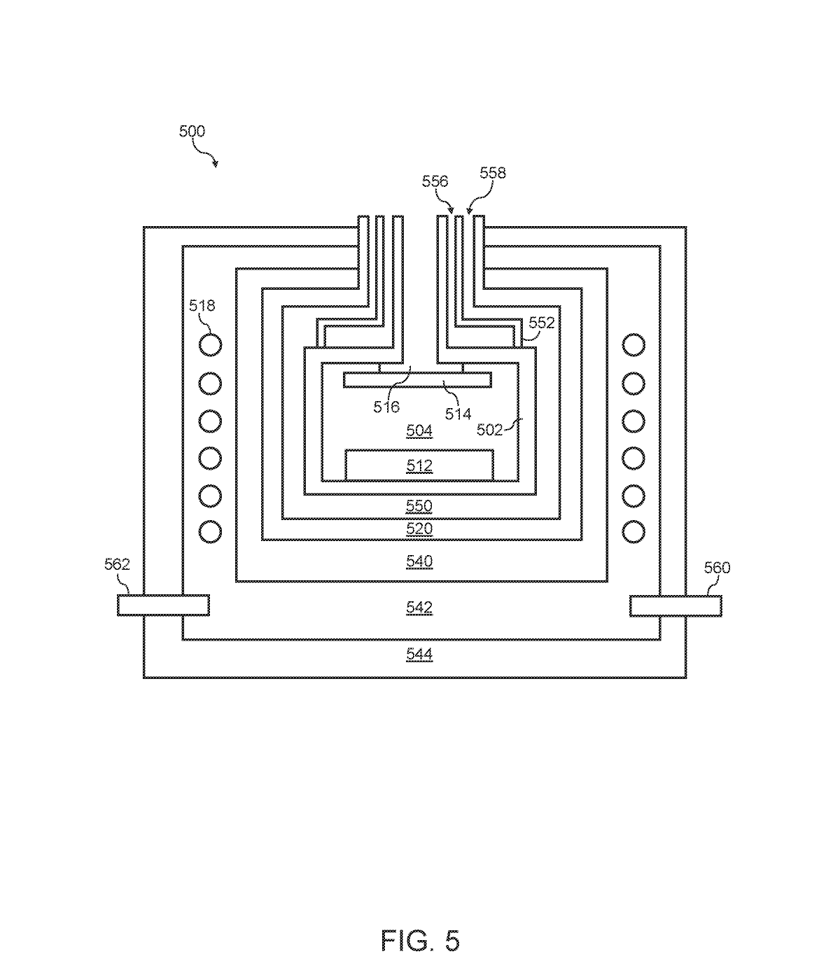

FIG. 3 is a simplified cross-sectional schematic diagram of a crystal growth system 300 adapted for use in a crystal growth process of the type contemplated by certain embodiments of the disclosure. Like the crystal growth systems of FIGS. 1 and 2, the crystal growth system 300 of FIG. 3 includes the reaction crucible 102, the crystal growth chamber 104, the source material 112, the seed crystal 114, the seed holder 116, the heater 118, the outer enclosure 144, and the outer chamber 142. The crystal growth system 300 contains insulation 340 on the inner surface of the outer enclosure 144.

However, in the crystal growth system 300 of FIG. 3, the heater 118 surrounds the outer enclosure 144. This configuration is particularly suitable when the heater 118 is an inductive (e.g., RF) heater and the outer enclosure 144 is a water-cooled quartz vessel. Similar to the crystal growth systems of FIGS. 1 and 2, the pressure P₁ within the crystal growth chamber 104 is less than the pressure P₂ within the outer chamber 142. While typical RF-heated systems do not expose the heater 118 to vapors escaping the reaction crucible 102, as it typically surrounds the outer enclosure 144, they do expose the insulation 340 to such vapors. As such, by operating the crystal growth system 300 such that P₂ is more than P₁, the insulation 340 may experience less evaporation/sublimation, providing it with a longer lifetime. Further, during the sublimation growth process, the outer chamber 142 may be essentially free of silicon containing vapor, which can also contribute to extending the lifespan of the insulation 340.

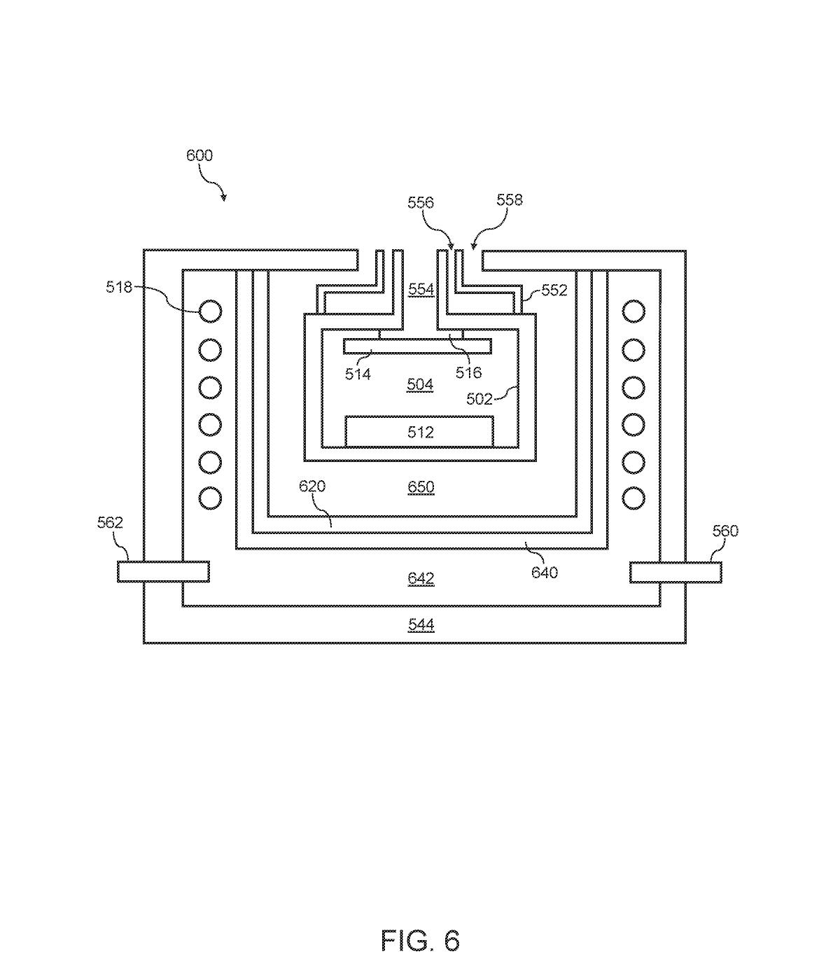

FIG. 4 is a simplified cross-sectional schematic diagram of a crystal growth system 400 adapted for use in a crystal growth process of the type contemplated by certain embodiments of the disclosure. Like the crystal growth systems of FIG. 3, the crystal growth system 400 of FIG. 4 includes the reaction crucible 102, the crystal growth chamber 104, the source material 112, the seed crystal 114, the seed holder 116, the heater 118, the insulation 340, the outer enclosure 144, and the outer chamber 142. The crystal growth system 400 also includes an interface structure 115 as described above with respect to FIG. 2. Like in FIG. 3, the heater 118 surrounds the outer enclosure 144.

Similar to the crystal growth systems of FIGS. 1-3, the pressure P₁ within the crystal growth chamber 104 is less than the pressure P₂ within the outer chamber 142. Further, during the sublimation growth process, the outer chamber 142 may be essentially free of silicon containing vapor.

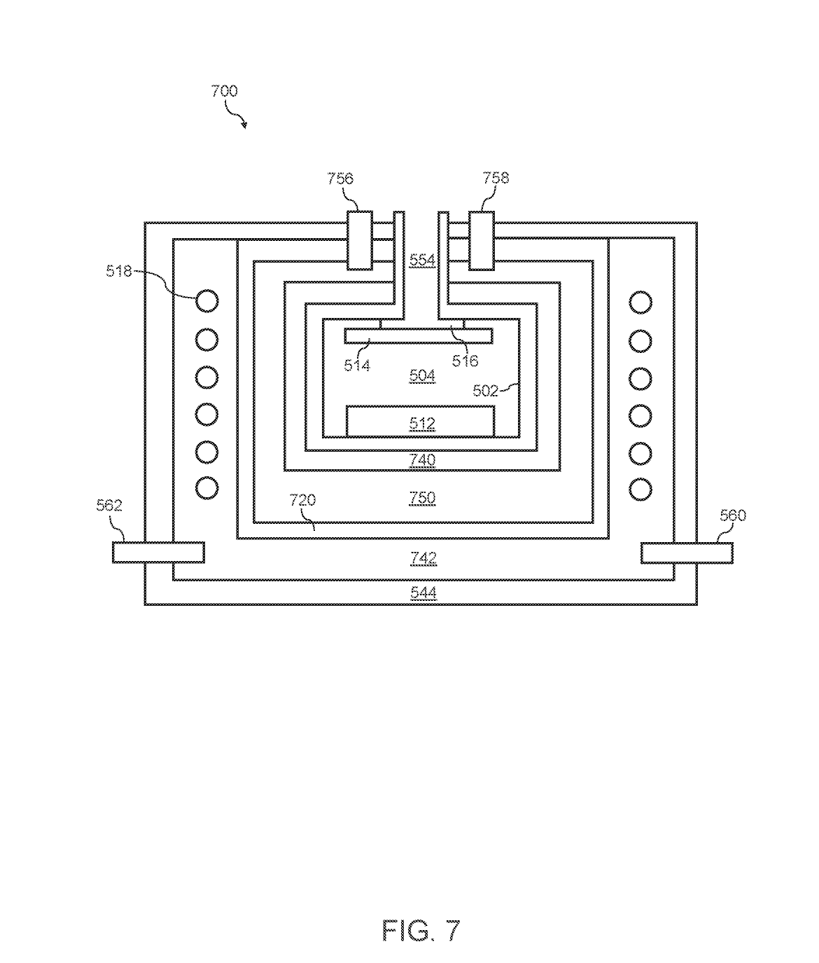

FIGS. 5-9 illustrate in more detail the various methods and configurations that can be employed to provide the outer chamber with higher pressure than the crystal growth chamber as in the crystal growth systems of FIGS. 1-4.

FIG. 5 is a simplified cross-sectional schematic diagram of a crystal growth system 500 adapted for use in a crystal growth process of the type contemplated by certain embodiments of the disclosure. The crystal growth system 500 includes a reaction crucible 502 containing a source material 512, a seed holder 516, and a seed crystal 514. The reaction crucible 502 is at least partially surrounded by a barrel (i.e., outer barrel) 520. Insulation 540 and heater 518 at least partially surround the barrel 520. An outer enclosure 544 at least partially surrounds the insulation 540 and the heater 518.

An intermediate chamber 550 is formed between the crucible 502 and the barrel 520. A gas trap 552 is positioned within the intermediate chamber 550 above the top of the crucible 502. Ventilation holes (not shown) may be formed in the top of the crucible 502 to let vapor that passes the growing crystal and/or seed crystal 514 escape into the gas trap. The crystal growth system 500 has a cylindrical pumping and feedthrough system extending through a gap in the top of the outer enclosure 544. The system includes, from inside to outside, a sight tube 554, an annular gas outlet 556 formed between the outer surface of the sight tube 554 and the inner surface of a stem portion of gas trap 552, and an annular gas inlet 558 formed between the outer surface of the stem portion of gas trap 552 and an inner surface of a stem portion of barrel 520. The annular gas outlet 556 and the annular gas inlet 558 may each be connected to a pump (not shown).

An outer chamber 542 is formed between the outer enclosure 544 and the barrel 520. The barrel 520 may be formed from an impermeable material in order to prevent gas flow between the outer chamber 542 and the intermediate chamber 550. In some embodiments, the impermeable material may be formed from graphite that has been modified to reduce its permeability. For example, the graphite may be coated with a polymer resin or glassy carbon. The polymer resin may be a glassy carbon precursor, such as a furan resin, that forms glassy carbon when exposed to high temperatures. Similarly, the pores of the graphite may be filled with the polymer resin or glassy carbon to reduce its permeability. The graphite may also be coated with a carbide with low permeability, such as tantalum or hafnium carbide. In some examples, the graphite can have a pyrolytic coating. Other suitable coatings may be used without deviating from the scope of the present disclosure, such as other carbide coatings, such as vanadium carbide, silicon carbide, etc. Example coatings that may be used are disclosed in U.S. Provisional Application Serial No. No. 63/700,682, filed on Sep. 28, 2024, U.S. Provisional Application Serial No. 63/700,685, filed on Sept. 28, 2024, and U.S. Provisional Application Serial No. 63/700,686, filed on Sept. 28, 2024, which are incorporated herein by reference. Overall, the nitrogen gas permeability of the barrel may be about 10⁻¹⁶ m² or less, such as about 10⁻¹⁷ m² or less, such as about 10⁻¹⁸ m² or less, such as about 10⁻¹⁹ m² or less, such as about 10⁻²⁰ m² or less, such as about 10⁻²¹ m² or less, such as about 10⁻²² m² or less.

The gas permeability of the crucible 502 is higher than that of the barrel 520. For example, the gas permeability of the crucible (e.g., formed from graphite) may be from about 10⁻¹² m² to about 10⁻¹⁵ m². However, it should be understood that the permeability of the crucible is not limited to any particular range. As such, gas may pass relatively readily between the intermediate chamber 550 and the crystal growth chamber 504. In this regard, gas pumped into the intermediate chamber 550 through annular gas inlet 558 may diffuse/flow into the crystal growth chamber 504 through the walls of crucible 502. Sublimation gasses from the crystal growth chamber 504 may also diffuse/flow into the intermediate chamber 550. However, due to the relative impermeability of the barrel 520, such vapor can be prevented from reaching the insulation 540 and the heater 518 in any substantial amount (e.g., the outer chamber 542 can remain essentially free of sublimated species from the crystal growth chamber).

The crystal growth system 500 has two separate pumping systems. The first system includes the annular gas outlet 556, the annular gas inlet 558, one or more pumps fluidly connected to the annular gas outlet 556 and the annular gas inlet 558, and one or more gas sources. The first pumping system controls the pressure and gas composition within the crystal growth chamber 504 and the intermediate chamber 550 which, as explained above, can interact with each other through the permeable crucible 502. The second pumping circuit can control the pressure and gas composition within the outer chamber 542. The second pumping circuit includes a gas inlet 560, optionally a gas outlet 562, and one or more pumps fluidly connected to gas inlet 560 and/or gas outlet 562. The first pumping system is separated from the second pumping system by the impermeable barrel 520. It should be understood that any “separated” pumping systems or circuits described herein may be implemented by using a separate pump for each system or a single a single pump with valving that is external to the growth chamber to create the “separate” systems. Furthermore, crystal growth systems including two separate pumping systems are described herein, but as would be understood by one of skill in the art with the benefit of this disclosure, additional pumping circuits are possible.

The first pumping system may be used to pump vapor out of the crystal growth chamber 504 to maintain low pressure within. As the vapor flows upward through the crystal growth chamber 504, some may be incorporated into the growing silicon carbide crystal. The rest may pass through ventilation holes in the top of the crucible 502 and into the annular gas outlet 556. Sublimated species that escape the crucible 502 may deposit on the gas trap 552 while inert gasses may continue through the annular gas outlet 556. The gas trap 552 may be disposable or contain a disposable portion such that it can be replaced as deposited material builds up on it.

The first pumping system may pump a gas from a gas source which may include dopant gas (e.g., N₂) into the annular gas inlet 558 optionally with an inert gas. The dopant may diffuse through the walls of the crucible 502 into the growth chamber 504 by pressure forces or stochastically where it can be incorporated into the growing silicon carbide crystal. The dopant concentration can be controlled by the first pumping system. In some embodiments, a carbon-containing gas such as but not limited to methane, carbon monoxide, propane, acetylene, etc. may also be pumped into the intermediate chamber 550 so that it can enter the crucible 502 and boost the carbon to silicon gas ratio. In addition, other gases may be provided into the chamber, including other reactive gases, such as silicon-containing gases, dopant-containing gases (e.g., n-type or p-type dopant containing gases), or other suitable gases. N-type dopant-containing gasses may include nitrogen- and phosphorus-containing gasses (e.g., N₂ and phosphine). P-type dopant containing gasses may include boron- and aluminum-containing gasses (e.g., boron trifluoride, diborane, trimethylboron). In some embodiments, sulfur- or halide-containing gasses may also be pumped into the intermediate chamber 550 to transport sublimated species to the growing crystal. In some embodiments, the first pumping system may also allow for convective flow of the sublimated vapor to enhance transport to the seed crystal 514 and/or the silicon carbide crystal growing therefrom. The reaction crucible 502 may contain structures designed to guide convective flow to desired areas within the growth chamber 504.

The second pumping system for the outer chamber 542 can be used to maintain a high pressure in the outer chamber 542, such as a pressure higher than that of the crystal growth chamber 504. In this regard, an inert gas may be pumped into the outer chamber through gas inlet 560. Alternatively, or in addition to, the inert gas, a carbon-containing gas (e.g., methane, CO, propane, acetylene, etc.) may be pumped into the outer chamber. The pressurized carbon-containing gas may slow the etching of the carbon-containing components such as the heater 518 and the insulation 540 within the outer chamber 542 by depositing carbon on the surfaces thereof. In some embodiments, a gas (e.g., CO) may be pumped into the outer chamber 542 to bind to a destructive gas species, such as silicon, oxygen, or hydrogen gasses. Further, in some embodiments, a halide- or sulfur-containing gas may be pumped into the outer chamber 542 to help keep any escaped silicon vapor in gaseous form so it does not deposit on the surfaces of heater 518 or insulation 540.

In the crystal growth system 500, the crucible 502 and the barrel 520 are movable within the outer enclosure 544. For example, the cylindrical pumping and feedthrough system can be moved vertically relative to the outer enclosure 544 and heater 518.

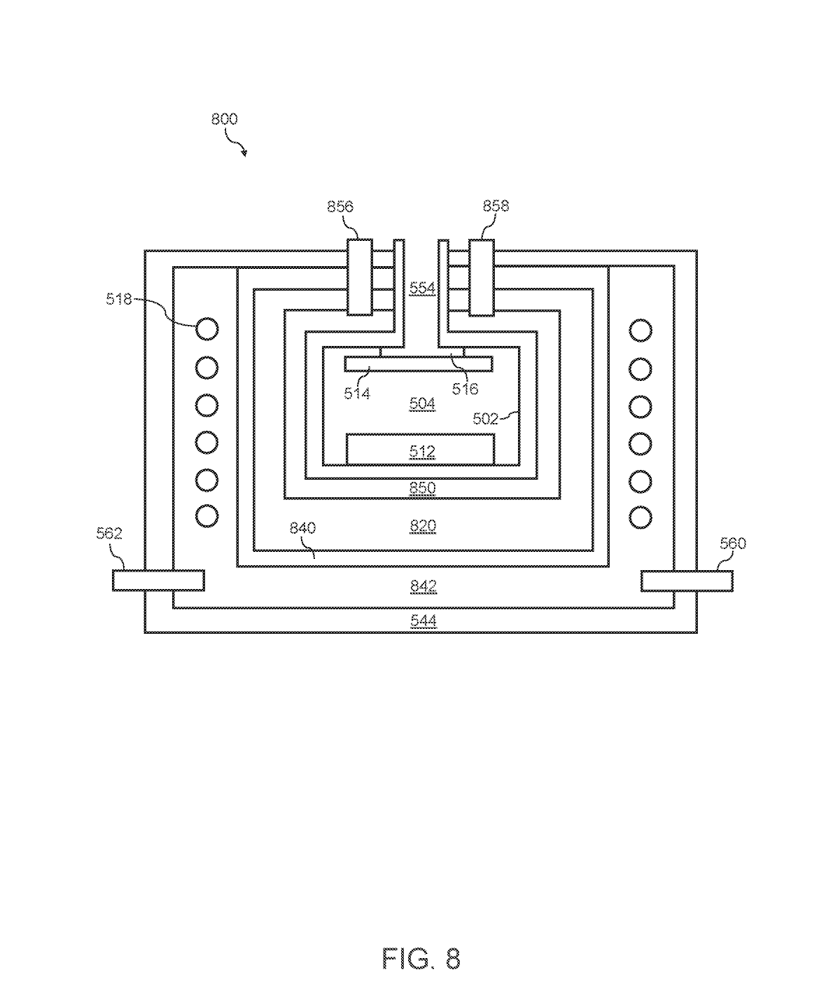

FIG. 6 is a simplified cross-sectional schematic diagram of a crystal growth system 600 adapted for use in a crystal growth process of the type contemplated by certain embodiments of the disclosure. The crystal growth system 600 is similar to crystal growth system 500 in FIG. 5 except that the barrel 620 is attached to the outer enclosure 544 rather than being movable with respect to the outer enclosure 544. For example, like the crystal growth system of FIG. 5, the crystal growth system 600 of FIG. 6 includes the outer enclosure 544, the heater 518, the reaction crucible 502, the crystal growth chamber 504, the source material 512, the seed holder 516, the seed crystal 514, the sight tube 554, the gas trap 552, the first pumping system including annular gas inlet 558 and annular gas outlet 556, and the second pumping system including gas inlet 560 and gas outlet 562.

It can be seen in FIG. 6 that the barrel 620 is attached to the top of outer enclosure 544 and that insulation 640 at least partially surrounds the barrel 620. This creates an intermediate chamber 650 between the barrel 620 and the reaction crucible 502 and an outer chamber 642 between the outer enclosure 544 and the barrel 620. Like the crystal growth system 500 in FIG. 5, the insulation 640 and the heater 518 are protected from the escape of sublimated vapor by the impermeable barrel 620. Similarly, the pressure and gas composition in the growth chamber 504 and the intermediate chamber 650 can be controlled by the first pumping system, while the pressure and gas composition in the outer chamber 642 can be separately controlled by the second pumping system.

In crystal growth system 600, the reaction crucible 502 is movable vertically with respect to the outer enclosure 544, the barrel 620, the insulation 640, and the heater 518. For example, the feedthrough and pumping system including the sight tube 554 and the stem portion of the gas trap 552 is movable within the gap in the top of the outer enclosure 544. While not shown, the outer enclosure 544 or a separate component attached to the outer enclosure 544 may at least partially surround the feedthrough and pumping system, providing the outer component of annular gas inlet 558. By attaching the barrel 620 to the outer enclosure 544, the structure of the feedthrough and pumping system can be simplified compared to crystal growth system 500 shown in FIG. 5.

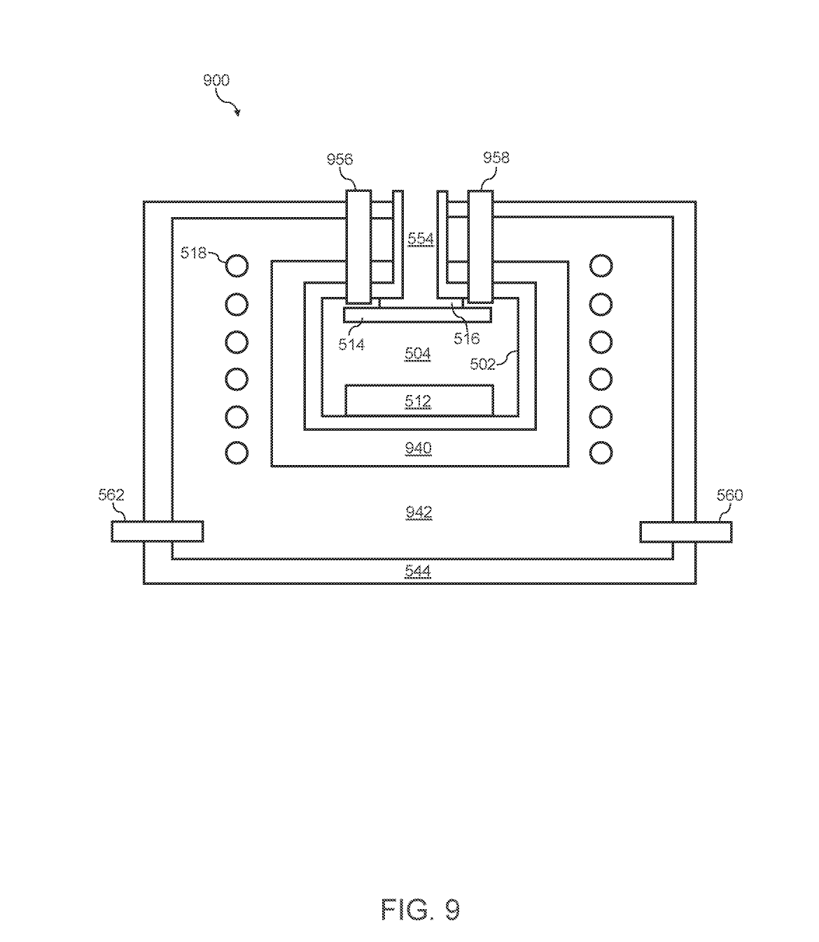

FIG. 7 is a simplified cross-sectional schematic diagram of a crystal growth system 700 adapted for use in a crystal growth process of the type contemplated by certain embodiments of the disclosure. The crystal growth system 700 is similar to the crystal growth systems in FIGS. 5 and 6 except that the first pumping system does not use the cylindrical feedthrough configuration. For example, like the crystal growth system of FIGS. 5 and 6, the crystal growth system 700 of FIG. 7 includes the outer enclosure 544, the heater 518, the reaction crucible 502, the crystal growth chamber 504, the source material 512, the seed holder 516, the seed crystal 514, the sight tube 554, and the second pumping system including gas inlet 560 and gas outlet 562.

Similar to crystal growth system 600 in FIG. 6, in crystal growth system 700, the barrel 720 is attached to the outer enclosure 544. However, in crystal growth system 700, the insulation 740 at least partially surrounds the reaction crucible 502, but is inside of the barrel 720. Rather than a cylindrical feedthrough pumping system, crystal growth system 700 includes a gas inlet 756 and a gas outlet 758 that are fluidly connected to one or more pumps and/or gas sources (e.g., containing a dopant gas, such as N₂).

An intermediate chamber 750 exists between the reaction crucible 502 and the barrel 720 and an outer chamber 742 exists between the barrel 720 and the outer enclosure 544. The first pumping system (e.g., gas inlet 756 and gas outlet 758) is configured to control the pressure and gas composition within the intermediate chamber 750 and, because of the permeable walls of the reaction crucible 502, indirectly control the pressure and/or gas composition of crystal growth chamber 504.

While crystal growth system 700 does not provide the same level of protection for the insulation 740 as in the systems of FIGS. 5 and 6, it still protects the heater 518 from sublimated vapor. Further, because the barrel 720 is impermeable, the pressure within the outer chamber 742 can be controlled independently from the pressure of intermediate chamber 750 and crystal growth chamber 504. As such, the second pumping system can maintain the pressure in outer chamber 742 higher than the pressure of the crystal growth chamber 504. Further, as gas inlet 756 and gas outlet 758 are not contained in a cylindrical feedthrough system, the pumping system is simplified compared to the systems shown in FIGS. 5 and 6. In crystal growth system 700, the reaction crucible 502 is movable vertically relative to the outer enclosure 544, the heater 518, and the barrel 720. The insulation 740 moves with the reaction crucible 502.

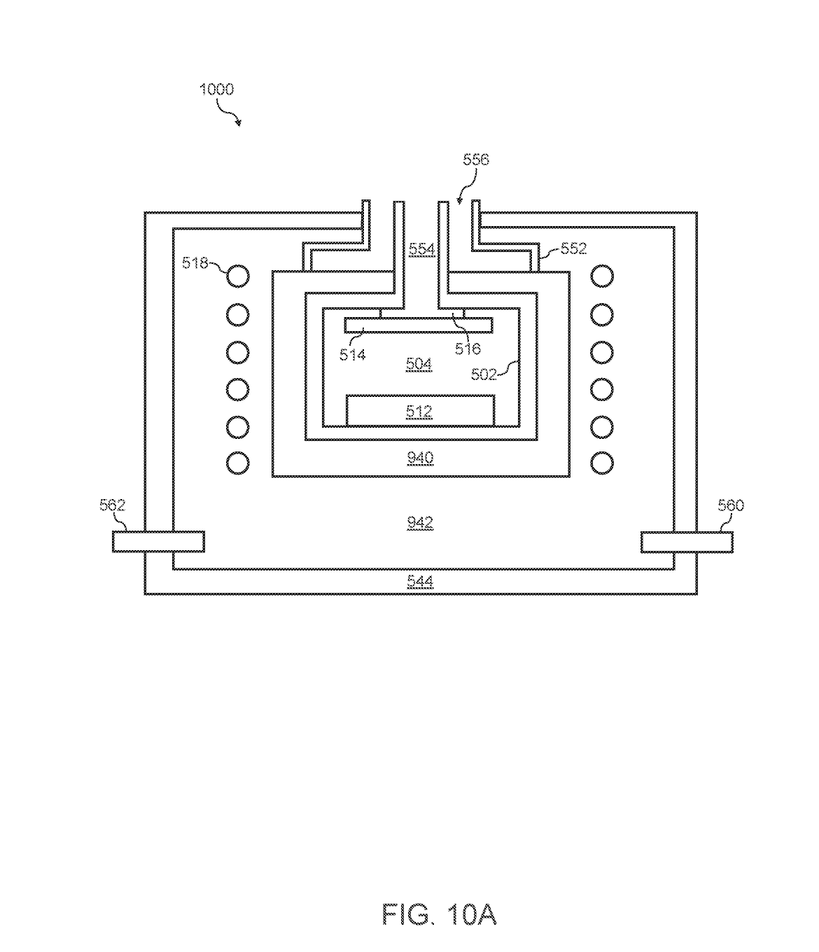

FIG. 8 is a simplified cross-sectional schematic diagram of a crystal growth system 800 adapted for use in a crystal growth process of the type contemplated by certain embodiments of the disclosure. Crystal growth system 800 is similar to crystal growth system 700 shown in FIG. 7 except that the insulation 840 is also outside of the barrel 820. For example, like the crystal growth system of FIG. 7, the crystal growth system 800 of FIG. 8 includes the outer enclosure 544, the heater 518, the reaction crucible 502, the crystal growth chamber 504, the source material 512, the seed holder 516, the seed crystal 514, the sight tube 554, and the second pumping system including gas inlet 560 and gas outlet 562.

In crystal growth system 800, the insulation 840 and the barrel 820 are attached to the upper part of the outer enclosure 544. Similar to FIG. 7, rather than a feedthrough pumping system, crystal growth system 800 includes a gas inlet 856 and a gas outlet 858 that are fluidly connected to one or more pumps and/or gas sources (e.g., containing a dopant gas, such as N₂). The gas inlet 856 and gas outlet 858 extend through the top of the barrel 820 and the insulation 840 and into intermediate chamber 850.

Intermediate chamber 850 exists between the reaction crucible 502 and the barrel 820 and an outer chamber 842 exists between the barrel 820 and the outer enclosure 544. The first pumping system (e.g., gas inlet 856 and gas outlet 858) is configured to control the pressure and gas composition within the intermediate chamber 850 and, because of the permeable walls of the reaction crucible 502, indirectly control the pressure and/or gas composition of crystal growth chamber 504.

Because the barrel 820 is impermeable, the pressure within the outer chamber 842 can be controlled independently from the pressure of intermediate chamber 850 and crystal growth chamber 504. As such, the second pumping system can maintain the pressure in outer chamber 842 higher than the pressure of the crystal growth chamber 504. In crystal growth system 800, the reaction crucible 502 is movable vertically relative to the outer enclosure 544, the heater 518, and the barrel 820, and the insulation 840. In addition to protecting the heater 518, the crystal growth system 800 also protects the insulation 840, as it surrounds the impermeable outer barrel and sits in the outer chamber 842.

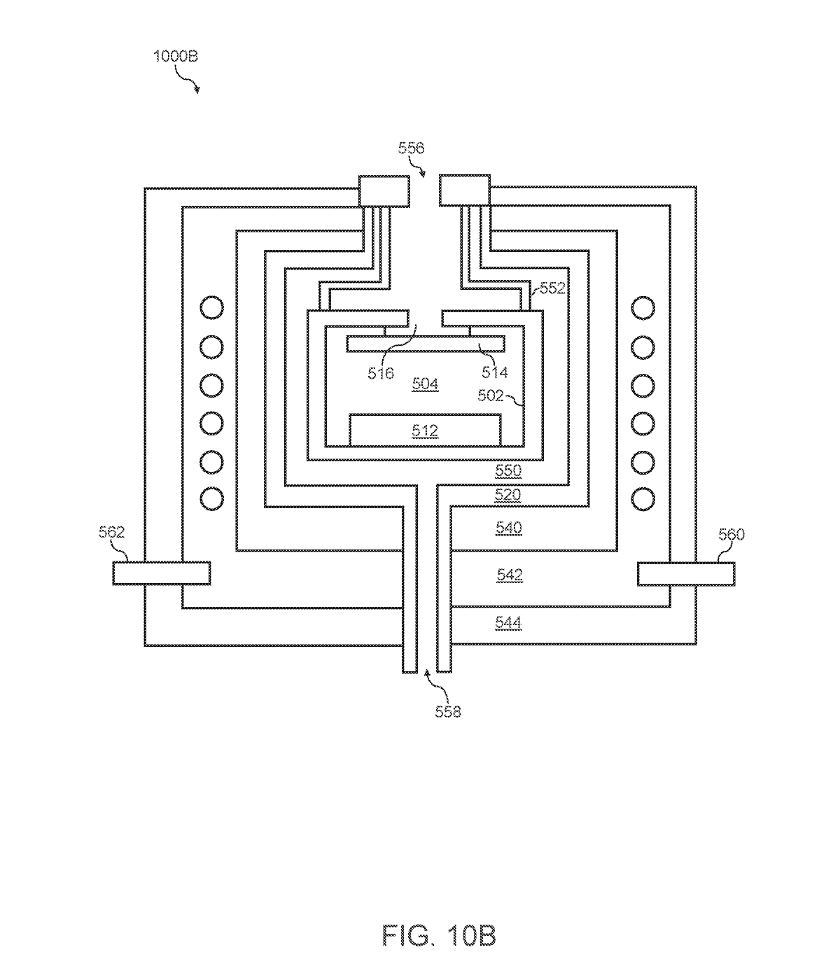

FIG. 9 is a simplified cross-sectional schematic diagram of a crystal growth system 900 adapted for use in a crystal growth process of the type contemplated by certain embodiments of the disclosure. Like the crystal growth systems of FIGS. 5 through 8, the crystal growth system 900 of FIG. 9 includes the outer enclosure 544, the heater 518, the crystal growth chamber 504, the source material 512, the seed holder 516, the seed crystal 514, the sight tube 554, and the second pumping system including gas inlet 560 and gas outlet 562.

Crystal growth system 900 does not contain an impermeable barrel. However, it employs a semipermeable reaction crucible 502 which is more permeable than the barrels described above but less permeable than a typical graphite crucible. For example, the semipermeable crucible may have a permeability from about 10⁻¹⁴ to about 10⁻¹⁸ m². The permeability may be controlled by modifying a graphite structure as described above for the impermeable barrel but to a lesser extent. For example, it may contain a filler or coating containing a polymer, glassy carbon, or a carbide, but less filler or a thinner coating than used for the impermeable barrel material. The modification may also be applied to the graphite in a pattern, leaving some permeable portions and some impermeable portions to achieve the overall desired permeability of the structure.

By using the semipermeable reaction crucible 502, some vapor can be transferred between crystal growth chamber 504 and outer chamber 942. Therefore, in this configuration, the second pumping system including gas inlet 560 and gas outlet 562 may be used to introduce a dopant (e.g., N₂) to the outer chamber 942. The concentration of the dopant in the outer chamber 942 can selected based on the desired level of crystal doping and the permeability of the semipermeable crucible 502.

The semipermeable crucible 502 may have a low enough permeability that the pressure in the outer chamber 942 can be higher than the pressure in the crystal growth chamber 504. This can be achieved by controlling the pressure of the crystal growth chamber 504 using the first pumping system including gas outlet 958 and optional gas inlet 956, which extend into the crystal growth chamber 504, and separately controlling the pressure of the outer chamber 942 using the second pumping system including gas inlet 560 and gas outlet 562. This configuration also allows for the use of convection within the crystal growth chamber 504 as desired. It should also be understood that the gas inlet 956 and the gas outlet 958 are not necessarily placed in the top of the reaction crucible 502. For example, gas inlet 956 may be placed in a bottom portion of the reaction crucible 502 to help drive sublimated vapor from the source material 512 toward the seed crystal 514.

Further, the first pumping system may also be used to provide a dopant to the crystal growth chamber 504. For example, the first pumping system may be connected to a dopant gas source (e.g., N₂).

In crystal growth system 900, the reaction crucible 502 and the insulation 940 may be movable along a vertical axis relative to the outer enclosure 544 and the heater 518.

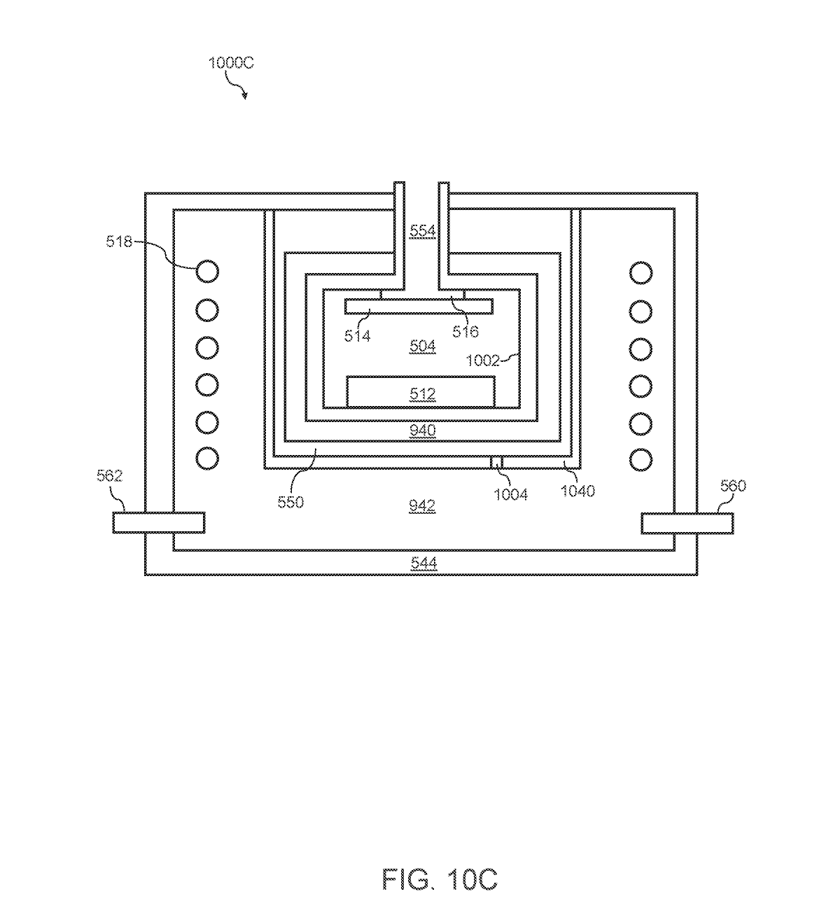

FIG. 10A is a simplified cross-sectional schematic diagram of a crystal growth system 1000 adapted for use in a crystal growth process of the type contemplated by certain embodiments of the disclosure. Like the crystal growth system of FIG. 9, the crystal growth system 1000 of FIG. 10A includes the outer enclosure 544, the heater 518, the crystal growth chamber 504, the source material 512, the seed holder 516, the seed crystal 514, the sight tube 554, insulation 940, outer chamber 942, and the pumping system including gas inlet 560 and gas outlet 562.

Crystal growth system 1000 also includes an annular gas outlet 556 which can remove vapor from the crystal growth chamber 504 as it passes up through the upper wall of the reaction crucible 502 and insulation 940 through optional ventilation holes (not shown) to reduce the pressure in the crystal growth chamber 504. Gas trap 552 may collect silicon vapor as it exits the crystal growth chamber 504 into the annular gas outlet 556. Similar to the crystal growth system 900 of FIG. 9, crystal growth system 1000 can have a semipermeable reaction crucible 502. The permeability can be controlled similarly to semipermeable reaction crucible described above with respect to FIG. 9. Any desired dopants can be introduced to the outer chamber 942 through gas inlet 560. They can then diffuse through the semipermeable reaction crucible 502 where they can be incorporated into the crystal. As crystal growth system 1000 does not contain a separate gas inlet to the crystal growth chamber 504 or an intermediate chamber, vapor may be removed at a slow rate through annular gas outlet 556. In this configuration, the pressure of the crystal growth chamber 504 may remain higher than that of outer chamber 942 during the sublimation process. However, by reducing the permeability of the reaction crucible 502 compared to a typical crucible, the pressure in the outer chamber 942 can be increased slightly without impacting the crystal growth rate. As such, the lifetime of the insulation 940 and the heater 518 can be increased compared to typical systems. In some embodiments, the system can be operated such that the pressure in the crystal growth chamber 504 remains lower than that of outer chamber 942 during the sublimation process.

In crystal growth system 1000, the reaction crucible 502, insulation 940, and gas trap 552 may be moved relative to the outer enclosure 544 and the heater 518.

FIG. 10B is a simplified cross-sectional schematic diagram of a crystal growth system 1000B adapted for use in a crystal growth process of the type contemplated by certain embodiments of the disclosure. The crystal growth system 1000B is similar to crystal growth system 500 shown in FIG. 5 except that the gas inlet 558 runs through the bottom of the outer enclosure 544, insulation 540, and barrel 520. Additionally, the reaction crucible is suspended from the top of the outer enclosure 544, eliminating the need for annular pump inlets and outlets. Like the crystal growth system of FIG. 5, the crystal growth system 1000B of FIG. 10B includes the outer enclosure 544, the heater 518, the reaction crucible 502, the crystal growth chamber 504, the source material 512, the seed holder 516, the seed crystal 514, the barrel 520, insulation 540, intermediate chamber 550, and the second pumping system including gas inlet 560 and gas outlet 562.

Rather than a feedthrough pumping system, crystal growth system 1000B includes a gas inlet 558 at the bottom of the system fluidly connected to intermediate chamber 550 and one or more pumps and/or gas sources (e.g., containing a dopant gas, such as N₂). The gas outlet 556 can remove vapor from the crystal growth chamber as it passes up through the upper wall of the reaction crucible 502 through optional ventilation holes (not shown) to reduce the pressure in the crystal growth chamber 504. Gas trap 552 may collect silicon vapor as it exits the crystal growth chamber 504 into the gas outlet 556.

Intermediate chamber 550 exists between the reaction crucible 502 and the barrel 520 and an outer chamber 542 exists between the barrel 520 and the outer enclosure 544. The first pumping system (e.g., gas outlet 556 and gas inlet 558) is configured to control the pressure and gas composition within the intermediate chamber 550 and crystal growth chamber 504. For example, as vapor (e.g., including a dopant) enters intermediate chamber 550 through gas inlet 558, it can diffuse through the walls of the reaction crucible 502 into the crystal growth chamber 504. Vapor can be removed through gas outlet 556 to maintain a low pressure within the crystal growth chamber 504.

Because the barrel 520 is impermeable, the pressure within the outer chamber 542 can be controlled independently from the pressure of intermediate chamber 550 and crystal growth chamber 504. As such, the second pumping system can maintain the pressure in outer chamber 542 higher than the pressure of the crystal growth chamber 504. In crystal growth system 1000B, the reaction crucible 502 is fixed relative to the outer enclosure 544, the heater 518, the barrel 820, and the insulation 840. In addition to protecting the heater 518, the crystal growth system 1000B also protects the insulation 540, as it surrounds the impermeable outer barrel and sits in the outer chamber 542.

FIG. 10C is a simplified cross-sectional schematic diagram of a crystal growth system 1000C adapted for use in a crystal growth process of the type contemplated by certain embodiments of the disclosure. Like the crystal growth system of FIG. 9, the crystal growth system 1000C of FIG. 10C includes the outer enclosure 544, the heater 518, the crystal growth chamber 504, the source material 512, the seed holder 516, the seed crystal 514, the sight tube 554, insulation 940, outer chamber 942, and the pumping system including gas inlet 560 and gas outlet 562.

Crystal growth system 1000C also includes a barrel 1040 at least partially surrounding reaction crucible 1002 creating an intermediate chamber 550. FIG. 10C shows an embodiment in which insulation 940 at least partially surrounds reaction crucible 1002 and is inside intermediate chamber 550. However, it should be understood that in other similar embodiments, insulation 940 can be moved outside of barrel 1040 to provide better protection for the insulation. Barrel 1040 is generally impermeable except for one or more small holes 1004 that allow vapor from outer chamber 942 to enter intermediate chamber 550.

Outer chamber 942 can be pressurized with gas including a dopant by the pumping system including gas inlet 560 and gas outlet 562. The vapor from outer chamber 942 including the dopant can enter intermediate chamber 550 through the one or more holes 1004. The pressure within the outer chamber 942 can be controlled to be higher than the pressure of the intermediate chamber 550 such that the pressure difference drives the vapor flow only one way (from outer chamber 942 to intermediate chamber 550) through hole(s) 1004, thus preventing the flow of any sublimated gasses (e.g., silicon) from entering the outer chamber 942, while providing a method for doping the crystal.

While FIG. 10C does not show a gas outlet for the crystal growth chamber 504, it should be understood that a gas outlet may be provided. Such an outlet may be similar to annular gas outlet 556 in FIG. 10A including a gas trap. The outlet may also be similar to outlet 958 in FIG. 9. If provided, the gas outlet can be used to reduce the pressure within the crystal growth chamber 504 and the intermediate chamber 550.

In crystal growth system 1000C, the reaction crucible 1002 and insulation 940 may be moved relative to the outer enclosure 544, the heater 518, and the barrel 1040.

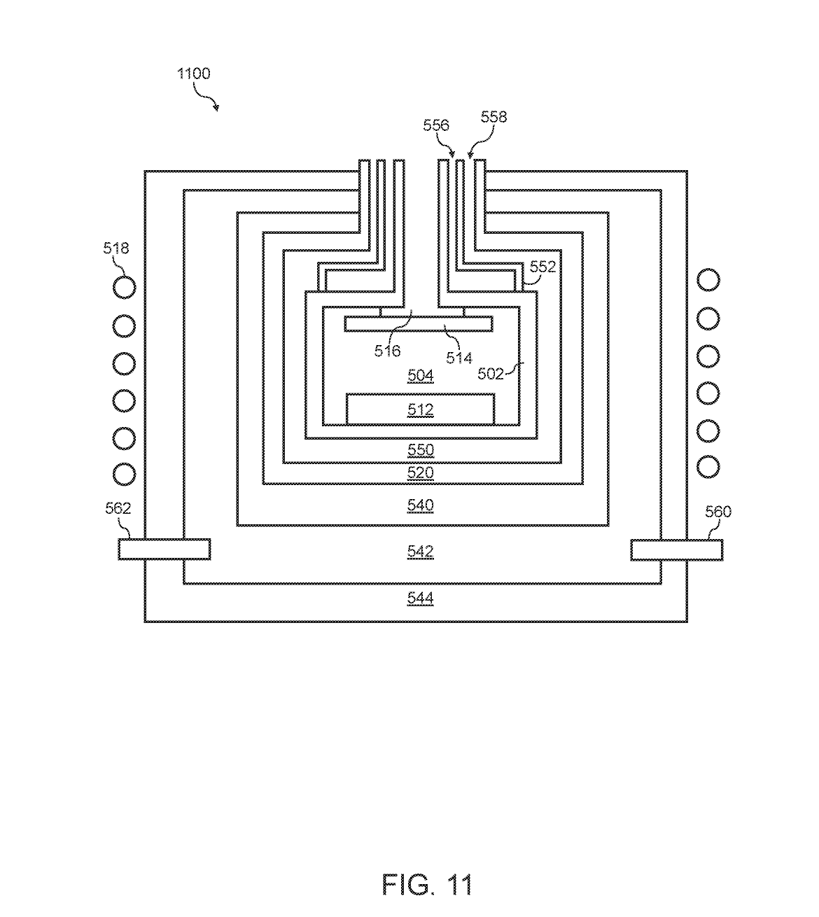

FIG. 11 is a simplified cross-sectional schematic diagram of a crystal growth system 1100 adapted for use in a crystal growth process of the type contemplated by certain embodiments of the disclosure. Like the crystal growth system of FIG. 5, the crystal growth system 1100 of FIG. 11 includes the outer enclosure 544, the reaction crucible 502, the crystal growth chamber 504, the source material 512, the seed holder 516, the seed crystal 514, the sight tube 554, the gas trap 552, the barrel 520, the insulation 540, the intermediate chamber 550, the outer chamber 542, the first pumping system including annular gas inlet 558 and annular gas outlet 556, and the second pumping system including gas inlet 560 and gas outlet 562. However, in crystal growth system 1100, heater 1118 is outside of the outer enclosure 544. This configuration is particularly suitable when the heater 1118 is an RF heater and the outer enclosure 544 is a water-cooled quartz enclosure. It should be understood that the crystal growth systems of FIGS. 6-10C may similarly be modified by moving the heater outside of the outer enclosure, particularly when using an RF heater and a quartz enclosure.

As described above, FIGS. 5-11 illustrate various configurations and methods for controlling the pressure with crystal growth systems so that the pressure outside the crystal growth chamber is higher than the pressure inside the crystal growth chamber or at least higher than is typically achievable (e.g., in the case of FIGS. 10A and 10C). These configurations and methods can be applied to produce the simplified crystal growth systems shown in FIGS. 1-4. For example, while FIGS. 1-4 are shown having a fully enclosed lid, it should be understood that any of the gas inlets, pumping systems, and feedthrough systems can be present in the crystal growth systems of FIGS. 1-4. Similarly, while the crystal growth systems of FIGS. 1-4 do not show the presence of any barrel creating an intermediate chamber, it should be understood that such features can be present in such systems and were not illustrated therein for the purpose of simplification. It should also be understood that the various configurations and methods described with respect to FIGS. 5-11 can be applied to any suitable crystal growth system. For example, similar to FIGS. 1-4, FIGS. 12-17 show simplified illustrations of more crystal growth systems in which the pressure outside of the crystal growth chamber can be increased, optionally to a pressure greater than that within the crystal growth chamber, as described herein and as described in detail above.

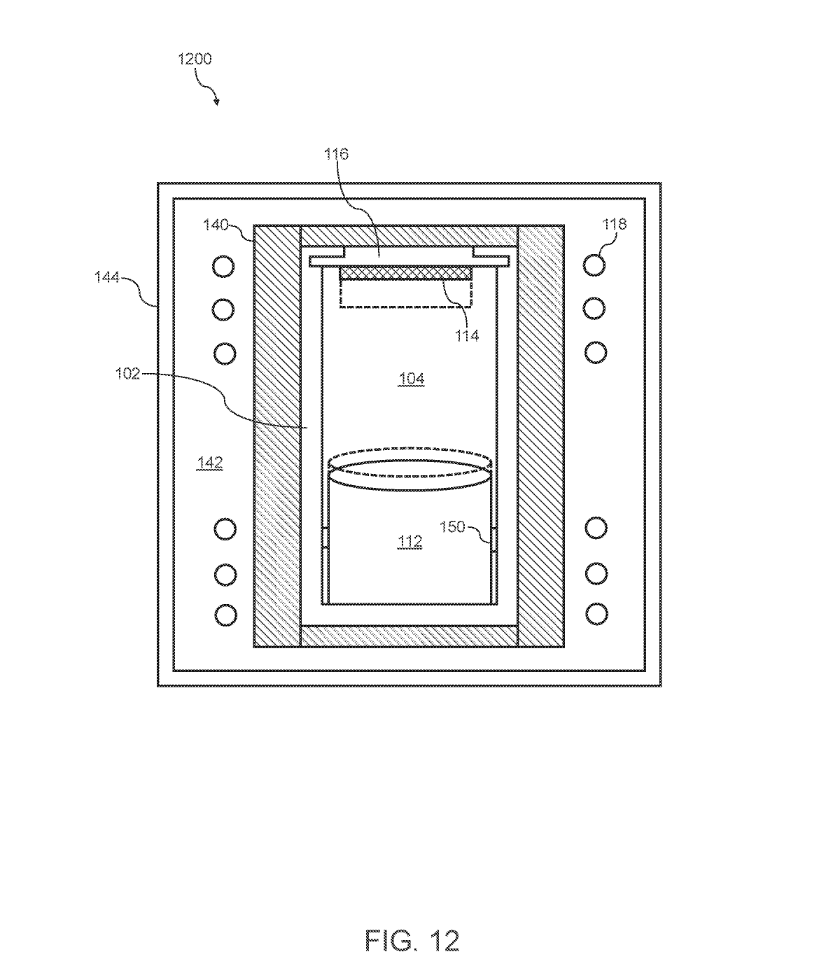

FIG. 12 is a cross-sectional schematic diagram of a crystal growth system 1200 adapted for use in a crystal growth process of the type contemplated by certain embodiments of the disclosure. The crystal growth system 1200 includes the reaction crucible 102 (also referred to as a susceptor or growth cell), the interior of which defines the crystal growth chamber 104. The crystal growth system 1200 includes a heater 118 (e.g., resistive heater) adapted to heat the reaction crucible 102. Alternatively, an inductive heating approach may be applied to the heating of the reaction crucible 102. Using any competent heating mechanism and approach, the temperature within the crystal growth system 1200 may be controllable. The reaction crucible 102 may be, at least in part, a graphite structure.

The crystal growth system 1200 may also include one or more gas inlet and gas outlet ports and associated equipment allowing the controlled introduction and evacuation of gas from an environment surrounding the reaction crucible 102, versions of which are described above with respect to FIGS. 5-11. The introduction and evacuation of various gasses to or from the environment surrounding the reaction crucible 102 may be accomplished using a variety of inlets/outlets, pipes, valves, pumps, gas sources, and controllers. The crystal growth system 1200 further includes an outer enclosure 144, which may be a metal structure or, in certain embodiments, a water-cooled quartz vessel. When the outer enclosure 144 is a water-cooled quartz vessel, the heater 118 may be an RF heater and located outside of the outer enclosure 144.

The reaction crucible 102 may be surrounded by an insulation material 140. The composition, size, and placement of the insulation material 140 will vary with an individual crystal growth system, such as the crystal growth system 1200 of FIG. 12, to define and/or maintain desired temperature profile (e.g., both axially and radially) in relation to the reaction crucible 102. An outer chamber 142 is defined between the outer enclosure 144 and the reaction crucible 102.

Prior to establishment of the temperature profile, the reaction crucible 102 is loaded with a source material 112 (e.g., silicon carbide vapor source material, such as a silicon carbide powder or solid silicon carbide source). As such, the reaction crucible 102 includes one or more portions, at least one of which is capable of providing the source material 112. The source material 112 may be held in a lower portion of the reaction crucible 102, as is common for one type of crystal growth system, such as the crystal growth system 1200 of FIG. 12.

The seed crystal 114 may be placed above or in an upper portion of the reaction crucible 102. The seed crystal 114 may take the form of a silicon carbide seed wafer having a diameter, for instance, from about 50 mm to about 310 mm or greater. A silicon carbide crystal boule may be grown from the seed crystal 114 during a crystal growth process.

In the embodiment illustrated in FIG. 12, the seed holder 116 is used to hold the seed crystal 114. The seed holder 116 is securely attached to the reaction crucible 102 in an appropriate fashion. For example, in the orientation illustrated in FIG. 12, the seed holder 116 is attached to an uppermost portion of the reaction crucible 102 to hold the seed crystal 114 in a desired position. In some embodiments, the seed holder 116 is fabricated from carbon (e.g., graphite). The attachment of the seed crystal 114 (e.g., a seed wafer) to the seed holder 116 within the crystal growth system 1200 may be made, for instance, by a uniform thermal contact or with a gap (e.g., freestanding seed) to permit radiative heat transfer.

Further, the crystal growth system 1200 may optionally include the source material holder 150. The source material holder 150 may be, for example, one or more graphite components within the reaction crucible 102 that brace, support, or hold the source material 112. In some embodiments, the source material holder 150 may be attached to the inner walls of the reaction crucible 102, as shown in FIG. 12.

During operation, the pressure may be controlled such that the pressure in the outer chamber 142 is greater than the pressuring in the crystal growth chamber 104. For example, the crystal growth system 1200 may include one or more pumping systems and/or non-permeable barrels allowing to separately control the pressure and/or vapor composition of the outer chamber 142 and the crystal growth chamber 104.

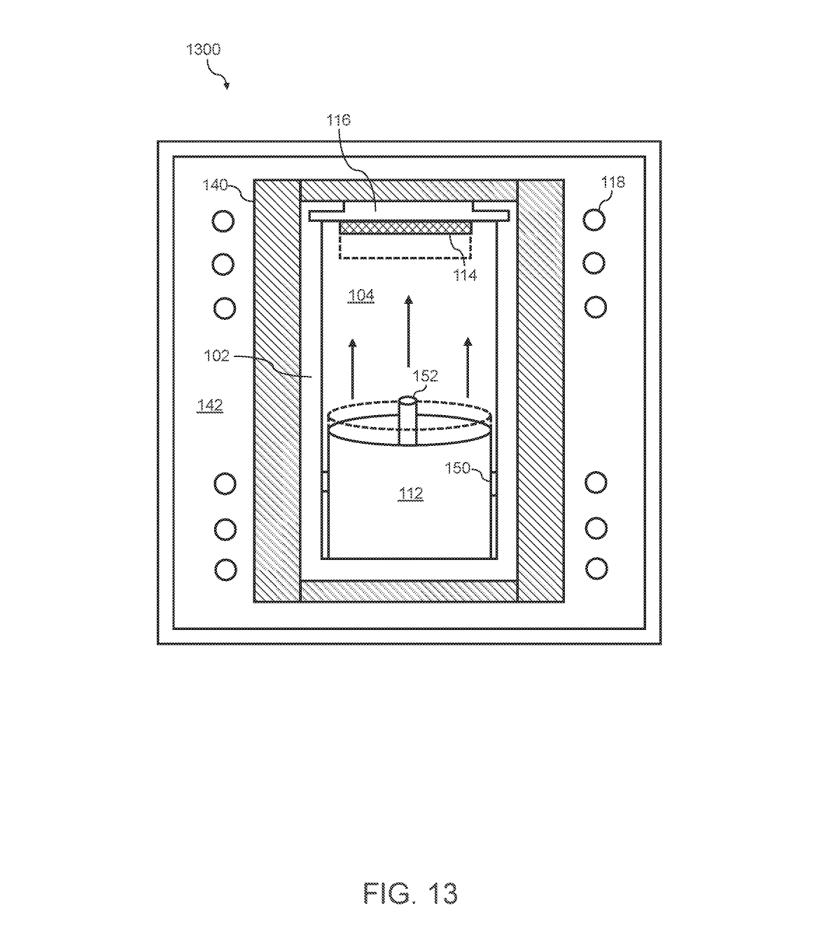

In one example embodiment, shown in FIG. 13, the crystal growth system 1300 may be similar to that shown in FIG. 12, but may also include an inlet 152 for introducing a dopant (e.g., N₂) to the reaction crucible 102. The inlet 152, may be, for example, a tube, pipe, vent, or the like. The inlet may be part of a pumping system as described above for controlling the pressure and/or gas composition within the crystal growth chamber 104. In some embodiments, the source material 112 may surround the inlet 152. For example, in some embodiments, the source material 112 may include a channel through which the inlet 152 is provided. In other embodiments, the source material 112 may include a plurality of subcomponents (attached or detached) which surround the inlet 152. The inlet 152 may be connected to a dopant-containing gas source (not shown) and configured to introduce the dopant-containing gas to the reaction crucible 102. An example of a dopant-containing gas is nitrogen.

During operation, the pressure may be controlled such that the pressure in the outer chamber 142 is greater than the pressuring in the crystal growth chamber 104. For example, the crystal growth system 1300 may include one or more pumping systems (including the inlet 152) and/or non-permeable barrels allowing to separately control the pressure and/or vapor composition of the outer chamber 142 and the crystal growth chamber 104.

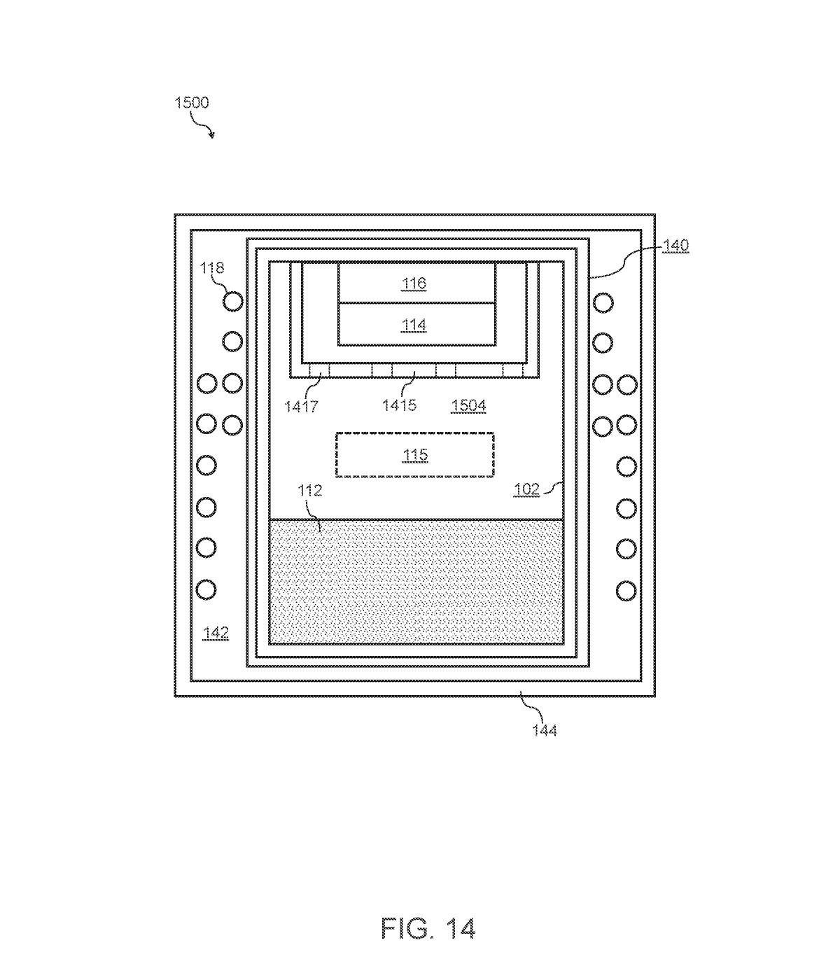

FIG. 14 depicts an example crystal growth system 1500 according to example embodiments of the present disclosure. In FIG. 14, the crystal growth system 1500 includes an interface structure 1415, the seed holder 116, the seed crystal 114, the reaction crucible 102, insulation 140, outer enclosure 144, outer chamber 142, heater 118, crystal growth chamber 1504, and the source material 112. The interface structure 1415 may be positioned such that the interface structure 1415 extends around at least three sides of the seed crystal 114, with the longest dimension located below the seed crystal 114. The interface structure 1415 may be referred to as a shell structure as it provides a shell around the seed crystal 114. The interface structure 1415 may be graphite, such as porous graphite. The interface structure 1415 may include one or more apertures 1417 that assist in the transport of source vapor from the source material 112 to the seed crystal 114.

In some examples, such as the example depicted in FIG. 14, the interface structure 1415 may or may not include any apertures 1417. The interface structure 1415 may be positioned such that the interface structure 1415 extends around at least three sides of the seed crystal 114, with the longest dimension located below the seed crystal 114. The system 1500 may include one or more optional second interface structures 115 within crystal growth chamber 1504. The one or more optional second interface structures 115 can be arranged in the vapor transport path from the source material 112 to the seed crystal 114.

During operation, the pressure may be controlled such that the pressure in the outer chamber 142 is greater than the pressure in the crystal growth chamber 104. For example, the crystal growth system 1500 may include one or more pumping systems and/or non-permeable barrels allowing to separately control the pressure and/or vapor composition of the outer chamber 142 and the crystal growth chamber 1504.

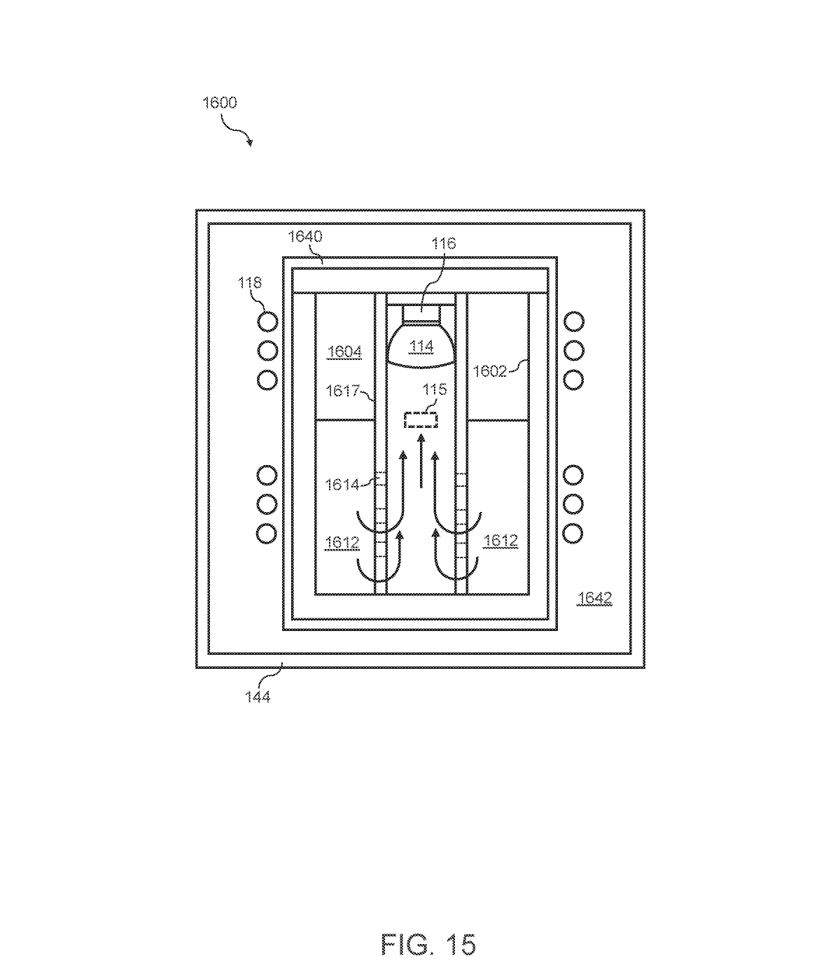

In FIG. 15, the crystal growth system 1600 includes a first interface structure 1617, an optional second interface structure 115, a seed holder 116, a seed crystal 114, a reaction crucible 1602, insulation 1640, outer enclosure 144, outer chamber 1642, heater 118, crystal growth chamber 1604, and the source material 1612. The first interface structure 1617 may include a tubular baffle structure. The seed crystal 114 may be within the first interface structure 1617. The optional second interface structure 115 may separate a first portion and a second portion of the crystal growth chamber 1604. The first interface structure 1617 or the optional second interface structure 115 may be graphite, such as porous graphite. The first interface structure 1617 may include one or more apertures 1614 that assist in the transport of source vapor from the source material 1612 to the seed crystal 114. The seed crystal 114 may be positioned at the top of the reaction crucible 1602. The first interface structure 1617 may or may not include apertures 1614.

During operation, the pressure may be controlled such that the pressure in the outer chamber 1642 is greater than the pressuring in the crystal growth chamber 1604. For example, the crystal growth systems 1600 may include one or more pumping systems and/or non-permeable barrels allowing to separately control the pressure and/or vapor composition of the outer chamber 1642 and the crystal growth chamber 1604.

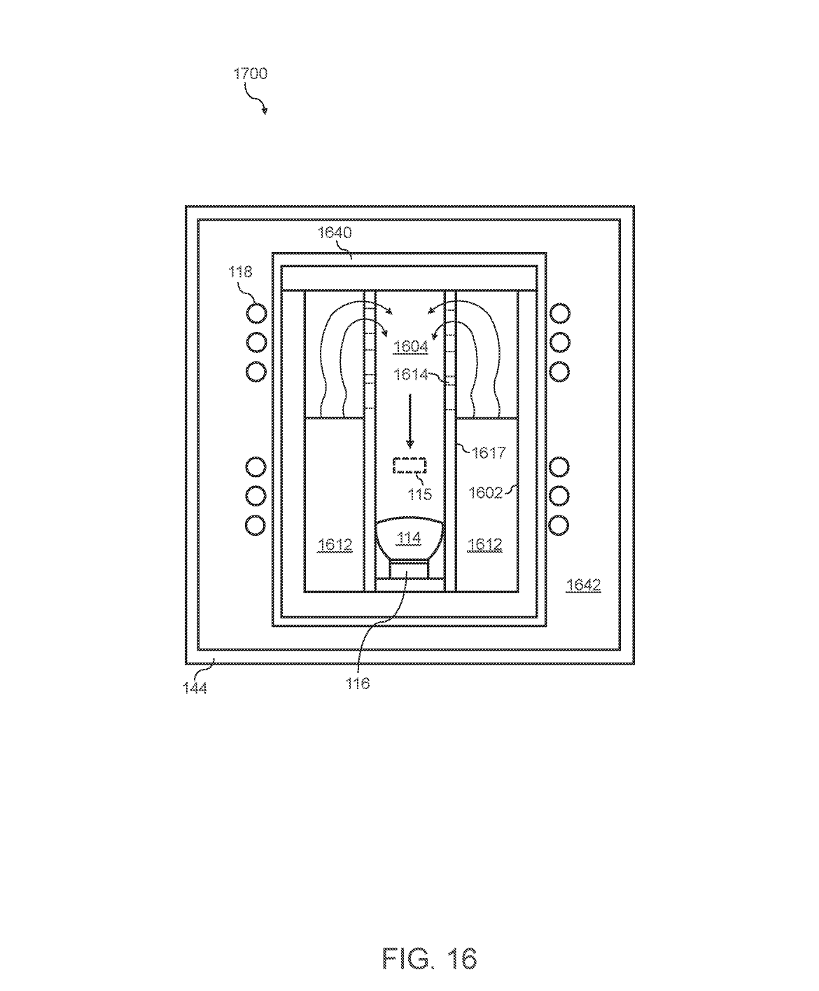

FIG. 16 depicts a crystal growth system similar to that of FIG. 15. In FIG. 16, the tubular interface structure 1617 may or may not include any apertures 1614. The system 1700 may further include one or more optional second interface structures 115. Source vapor may be transported through the first interface structure 1617 or the optional second interface structure 115. The optional second interface structure may separate a first portion and a second portion of the crystal growth chamber 1604. The first interface structure 1617 and/or the optional second interface structure 115 may reduce graphite inclusions or other impurities resulting from gravitational forces pulling impurities toward the seed crystal 114.

During operation, the pressure may be controlled such that the pressure in the outer chamber 1642 is greater than the pressuring in the crystal growth chamber 1604. For example, the crystal growth system 1700 may include one or more pumping systems and/or non-permeable barrels allowing to separately control the pressure and/or vapor composition of the outer chamber 1642 and the crystal growth chamber 1604.

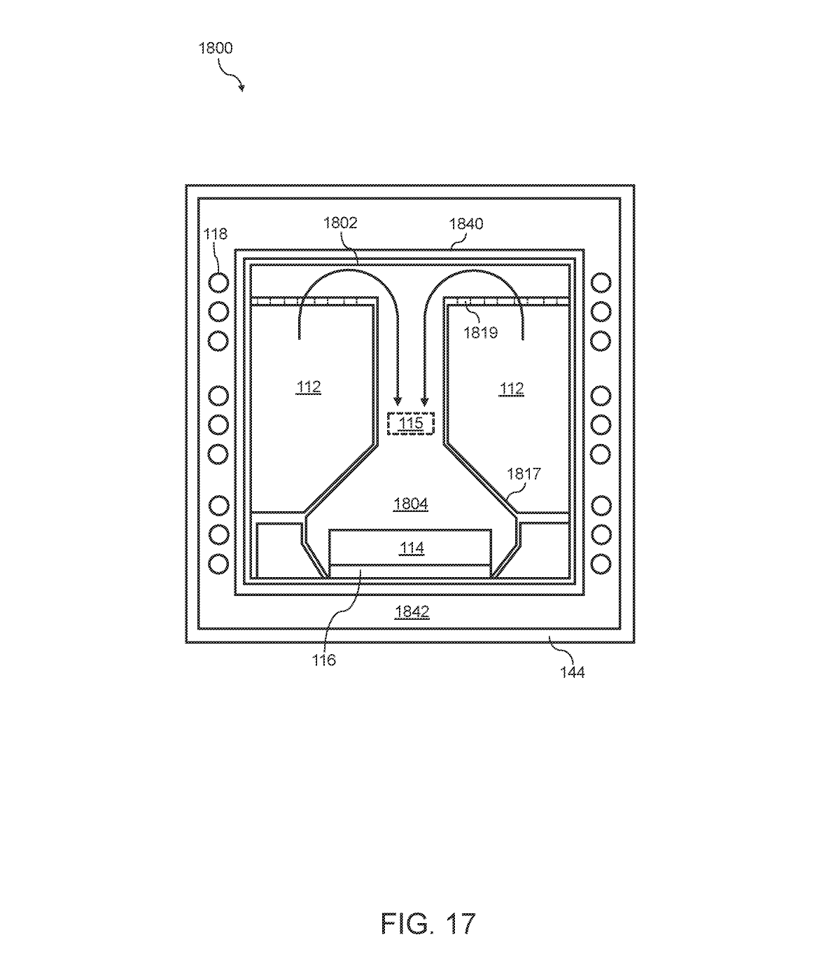

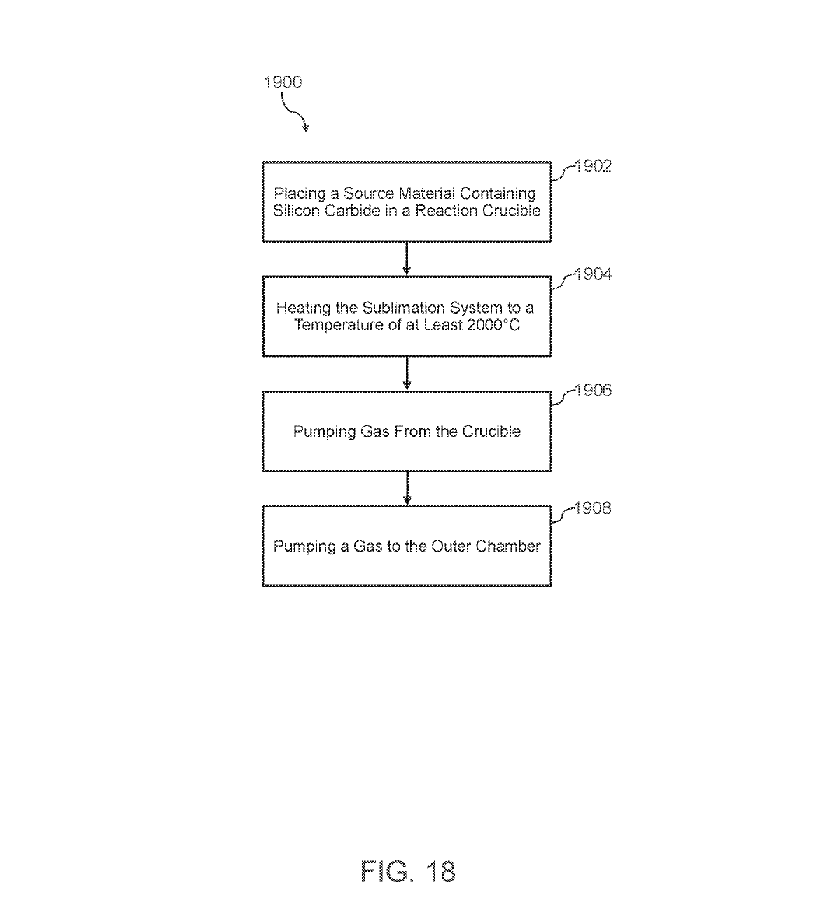

FIG. 17 depicts an example crystal growth system 1800 according to example embodiments of the present disclosure. In FIG. 18, the crystal growth system 1800 includes the seed holder 116 and the seed crystal 114 arranged within the reaction crucible 1802. The crucible 1802 may have one or more angled sidewalls. The crystal growth system 1800 includes the source material 112. The interface structure 1817 may be on top of the source material 112 and may separate the source material 112 from the reaction chamber defined by the crucible 1802. Insulation 1840 surrounds the crucible 1802 and an outer chamber 1842 is formed between the reaction crucible 1802 and the outer enclosure 144. As depicted in FIG. 18, the interface structure 1817 may include one or more apertures 1819 to assist with vapor transport from the source material 112 to the seed crystal 114.

The system 1800 may further include an optional second interface structure 115. The optional second interface structure 115 may be in the transport path between the source material 112 and the seed crystal 114. Source vapor may be transported through the first interface structure 1817 and/or the optional second interface structure 115 to the seed crystal 114. The interface structure 1817 and/or the optional interface structure 115 may serve to reduce graphite inclusions or other impurities resulting from gravitational forces pulling impurities toward the seed crystal 114.

During operation, the pressure may be controlled such that the pressure in the outer chamber 1842 is greater than the pressuring in the crystal growth chamber 1804. For example, the crystal growth system 1800 may include one or more pumping systems and/or non-permeable barrels allowing to separately control the pressure and/or vapor composition of the outer enclosure 1842 and the crystal growth chamber 1804.

For any of the crystal growth systems provided herein, one or more parts of the crystal growth system or the source material may be 3D printed, such as disclosed in U.S. Provisional Application Serial No. 63/689,298, which is incorporated herein by reference.

FIG. 18 depicts a flow chart of an example method 1900 according to example embodiments of the present disclosure. The method 1900 may be implemented, for instance, using the crystal growth systems shown in FIGS. 1-17. The method 1900 depicts operations performed in a particular order for purposes of illustration and discussion. Those of ordinary skill in the art, using the disclosures provided herein, will understand that the operations of any of the methods described herein may be adapted, expanded, performed simultaneously, omitted, rearranged, include steps not illustrated, and/or modified in various ways without deviating from the scope of the present disclosure.

In general, method 1900 is a method for growing a single-crystal of silicon carbide (SiC crystal) using a physical vapor transport (PVT) process in a sublimation system. At (1902), method 1900 may include placing a source material containing silicon carbide in a reaction crucible. The source material may comprise a solid source material or loose (i.e., non-bound) SiC powder.

At (1904), method 1900 may comprise heating the sublimation system to at least a sublimation temperature of the silicon carbide source material structure, such as at least 1800°C, such as at least 2000°C. For example, a typical SiC sublimation process is described as follows. However, those familiar with the growth of crystals, particularly in difficult material systems such as silicon carbide, will recognize that the details of the given technique can vary depending on relevant circumstances.

Typically, growth pressure during an applied PVT process will range from about 0.1 to 400 Torr, and more typically between about 0.1 and about 100 Torr. The process temperature will range from about 1800°C to about 3000°C, such as from about 2000°C to about 3000°C, and in some embodiments, from about 2000°C to about 2500°C. These conditions may vary due to differences in the sublimation system being used and variations in the seeded sublimation growth process being run. The thermal gradient between the growing crystal and the source material is typically controlled in a range of about 50 to 150°C/cm. A sublimating SiC species flux during the process period may be controlled by a ramped increase in the growth temperature in the range of about 0.3 to about 10°C/hr.

The sublimation process may include the steps of first evacuating the environment around the reaction crucible to remove ambient air, gaseous impurities and extraneous solid particulates. Then, the reaction crucible may be placed under pressure using one or more inert gas(es). This may be achieved using the pumping systems described herein. Then, the sublimation system may heat the reaction crucible environment to a temperature enabling SiC crystal growth via PVT. Once this temperature is reached, the pressure within the sublimation system may be reduced to a point sufficient to initiate SiC crystal growth. This may be achieved using the pumping systems described herein. In some embodiments, one or more carrier gasses (e.g., H₂, CH₄, Cl) may be used to increase growth rate or control the ratio of Si to C in the vapor.

In certain embodiments of the present disclosure, one or more types of dopant atoms may be intentionally introduced into sublimation system during or before the seeded sublimation process. For example, one or more dopant gases may be introduced into the seeded sublimation environment and thereby incorporated into the growing SiC crystalline boule. Dopants may be selected for their acceptor or donor capabilities in accordance with the conductivity properties desired for the resulting SiC boule. For certain semiconductor devices, donor dopants produce n-type conductivity and acceptor dopants produce p-type conductivity. Some commonly incorporated n-type dopants include N, P, As, Sb, and/or Ti. Some commonly incorporated p-type dopants include B, Al, Ga, Be, Er, and/or Sc.

With reference again to FIG. 1, in a typical sublimation growth process according to some embodiments, an electrical current having a defined frequency to which the material (e.g., carbon) forming reaction crucible 102 will respond is passed through heater 118 to heat reaction crucible 102. Alternatively, resistive heaters may convert the electrical current to heat. The amount and placement of insulation material 140 are selected to create a thermal gradient between a source material 112 and a seed crystal 114. Reaction crucible 102 is heated with source material 112 to a sublimation temperature above about 1800°C. In this manner, a thermal gradient is established such that the temperature of seed crystal 114 and the SiC crystalline boule growing on the seed crystal 114 remains slightly below the temperature of source material 112. In this manner, certain vaporized species generated from the sublimating SiC source (e.g., Si, Si₂C and/or SiC₂) are thermodynamically transported first to seed crytal 114 and thereafter to the growing SiC crystalline boule (or “the SiC crystal”). The SiC crystal may have a 4H crystal structure, 6H crystal structure, 3C crystal structure, or other crystal structure, depending on the seed material used.

As described herein, during sublimation, the process may involve operating the system such that the pressure inside the crystal growth chamber within the crucible is lower than the pressure in an outer chamber at least partially surrounding the crucible. For example, the pressure within the crystal growth chamber may be from about 0.1 to about 400 Torr, such as from about 0.1 to about 250 Torr, such as from about 0.1 to about 100 Torr, such as from about 0.1 to about 50 Torr, such as from about 0.1 to about 25 Torr, such as from about 0.1 to about 20 Torr, while the pressure within the outer chamber may be from about 5 to about 750 Torr, such as from about 20 Torr to about 750 Torr, such as from about 50 Torr to about 750 Torr, such as from about 100 Torr to about 750 Torr, such as from about 200 Torr to about 750 Torr, such as from about 400 Torr to about 750 Torr. The ratio of pressure within the crucible to the pressure in the outer chamber may be less than 1, such as about 0.9 or less, such as about 0.8 or less, such as about 0.7 or less, such as about 0.6 or less, such as about 0.5 or less, such as about 0.4 or less, such as about 0.3 or less, such as about 0.2 or less, such as about 0.1 or less.

To achieve these pressure ratios, method 1900 may comprise pumping gas from the crucible at (1906) and pumping a gas to the outer chamber at (1908). Of course, pumping the gas from the crucible and pumping the gas to the outer chamber may be performed simultaneously throughout the sublimation process and/or may be performed in any order. Pumping the gas to the outer chamber can involve using a pumping system to pump gas through a gas inlet fluidly connected to the outer chamber. In some embodiments, the gas pumped to the outer chamber may contain a carbon-containing gas (e.g., methane, CO, etc.); a silicon-, oxygen-, or hydrogen-binding gas; and/or a halide- or sulfur-containing gas.

Pumping gas from the crucible can involve using a pumping system to pump gas through a gas outlet fluidly connected to the crystal growth chamber, such as through ventilation holes in the crucible walls or lid and optionally through a gas trap, as described herein. In some embodiments, the method also involves pumping a gas to the crystal growth chamber. The gas can be pumped to the crystal growth chamber directly or can be pumped to an intermediate chamber, as described herein, where it can diffuse into the crystal growth chamber. The gas pumped directly or indirectly to the crystal growth chamber may contain methane and/or a dopant (e.g., N₂) optionally with an inert gas.

Once the SiC crystal has reached a desired size, the crystal growth process may be terminated by reducing the temperature of sublimation system below about 1900° C. and/or raising the pressure of the environment surrounding reaction crucible above about 400 Torr, which may be achieved using a pumping system as described herein.

Wafers cut from such SiC crystals may be subsequently used in the fabrication of various substrates. For example, using known techniques, high quality semiconductor wafers may be fabricated that include homo-epitaxial layers, such as SiC, as well as hetero-epitaxial layers, such as Group III-nitrides, on at least one surface thereof. The Group III-nitride layer may be, for example, GaN, AlGaN, AlN, AlInGaN, InN, and/or AlInN.

The SiC substrate may include at least one and possibly two primary (and opposing) surfaces. A plurality of active and/or passive devices may be fabricated on the SiC substrate.

For any of the crystal growth systems provided herein, one or more parts of the crystal growth system or the source material may be 3D printed, such as disclosed in U.S. Application Serial No. 18/963,082, which is incorporated herein by reference. For instance, in some embodiments, the 3D printed source may include a silicon carbide powder and a binder (e.g., UV curable polymer adhesive). In some embodiments, the 3D printed part may include a ceramic material (e.g., silicon carbide, metal mixed with carbon, etc.) and a binder (e.g., UV curable polymer adhesive).

Example aspects of the present disclosure are set forth below. Any of the below features or examples may be used in combination with any of the embodiments or features provided in the present disclosure.

In an aspect, the present disclosure provides an example silicon carbide crystal growth sublimation system. The system comprises an outer enclosure, a crucible within the outer enclosure, and an outer chamber between the crucible and the outer enclosure. The system is configured such that during a sublimation process a pressure within the crucible is less than a pressure within the outer chamber.

In some implementations, the example silicon carbide crystal growth sublimation system further comprises an insulation material at least partially surrounding the crucible and within the outer chamber.

In some implementations, the example silicon carbide crystal growth sublimation system further comprises a heater at least partially surrounding the crucible and within the outer chamber.

In some implementations of the example silicon carbide crystal growth sublimation system, the heater includes a resistive heating coil.

In some implementations, the example silicon carbide crystal growth sublimation system further comprises a heater at least partially surrounding the outer enclosure.

In some implementations of the example silicon carbide crystal growth sublimation system, the heater includes an RF heating coil.

In some implementations of the example silicon carbide crystal growth sublimation system, the outer enclosure includes quartz.

In some implementations, the example silicon carbide crystal growth sublimation system further comprises a barrel at least partially surrounding the crucible and between the crucible and the outer enclosure.

In some implementations of the example silicon carbide crystal growth sublimation system, the crucible has a higher gas permeability than the barrel.

In some implementations of the example silicon carbide crystal growth sublimation system, the barrel includes graphite.

In some implementations of the example silicon carbide crystal growth sublimation system, the graphite is coated with a polymer resin or glassy carbon.

In some implementations of the example silicon carbide crystal growth sublimation system, the graphite includes pores filled with a polymer resin or glassy carbon.

In some implementations of the example silicon carbide crystal growth sublimation system, the barrel includes a composition comprising the graphite and tantalum or hafnium carbide.

In some implementations, the example silicon carbide crystal growth sublimation system further comprises an intermediate chamber between the crucible and the barrel.

In some implementations of the example silicon carbide crystal growth sublimation system, the crucible includes a gas outlet.

In some implementations, the example silicon carbide crystal growth sublimation system further comprises a gas trap between the gas outlet and the intermediate chamber.

In some implementations, the example silicon carbide crystal growth sublimation system further comprises a gas inlet configured to introduce a gas to the intermediate chamber.

In some implementations of the example silicon carbide crystal growth sublimation system, the gas inlet is fluidly connected to a dopant gas source.

In some implementations of the example silicon carbide crystal growth sublimation system, at least a portion of the gas inlet at least partially surrounds at least a portion of the gas outlet.

In some implementations of the example silicon carbide crystal growth sublimation system, the crucible and the barrel are configured to be movable along at least one axis with respect to the outer enclosure.

In some implementations of the example silicon carbide crystal growth sublimation system, a portion of the barrel is attached to a portion of the outer enclosure.

In some implementations of the example silicon carbide crystal growth sublimation system, the crucible is configured to be movable along at least one axis with respect to the barrel and the outer enclosure.

In some implementations, the example silicon carbide crystal growth sublimation system further comprises a pump configured to pump gas from the crucible.

In some implementations, the example silicon carbide crystal growth sublimation system further comprises a silicon carbide source material within the crucible.

In some implementations, the example silicon carbide crystal growth sublimation system further comprises a silicon carbide seed crystal within the crucible.

In some implementations, the example silicon carbide crystal growth sublimation system further comprises a gas inlet configured to introduce a gas to the outer chamber.

In some implementations of the example silicon carbide crystal growth sublimation system, the gas inlet is fluidly connected to a pump.

In some implementations, the example silicon carbide crystal growth sublimation system further comprises a gas outlet configured to transport gas from the crucible.

In some implementations of the example silicon carbide crystal growth sublimation system, the gas outlet is fluidly connected to a pump.

In some implementations of the example silicon carbide crystal growth sublimation system, the outer chamber includes a carbon-containing gas.

In some implementations of the example silicon carbide crystal growth sublimation system, the carbon-containing gas includes methane.

In some implementations of the example silicon carbide crystal growth sublimation system, the outer chamber includes a silicon-, oxygen-, or hydrogen-binding gas.

In some implementations of the example silicon carbide crystal growth sublimation system, the outer chamber includes a halide- or sulfur-containing gas.

In some implementations of the example silicon carbide crystal growth sublimation system, the crucible contains methane.

In an aspect, the present disclosure provides an example silicon carbide crystal growth sublimation system. The system comprises an outer enclosure, a crucible within the outer enclosure, and an outer chamber between the crucible and the outer enclosure. The crucible comprises one or more walls comprising graphite and having a nitrogen gas permeability of 10⁻¹⁶ m² or less.

In some implementations of the example silicon carbide crystal growth sublimation system, the graphite is coated with a polymer resin or glassy carbon,

In some implementations of the example silicon carbide crystal growth sublimation system, the graphite includes pores filled with a polymer resin or glassy carbon.

In some implementations of the example silicon carbide crystal growth sublimation system, the graphite is modified with tantalum or hafnium carbide.

In some implementations of the example silicon carbide crystal growth sublimation system, the system is a closed system.

In an aspect, the present disclosure provides an example silicon carbide crystal growth sublimation system. The system comprises an outer enclosure, a crucible within the outer enclosure, and an outer chamber between the crucible and the outer enclosure. The system is configured such that during a sublimation process the outer chamber is essentially free of silicon-containing vapor.

In some implementations of the example silicon carbide crystal growth sublimation system, essentially free means that the concentration of silicon vapor is about 1000 ppm or less.

In some implementations of the example silicon carbide crystal growth sublimation system, the outer chamber includes a carbon-containing gas.

In some implementations of the example silicon carbide crystal growth sublimation system, the carbon-containing gas includes methane.

In some implementations of the example silicon carbide crystal growth sublimation system, the outer chamber includes a silicon-, oxygen-, or hydrogen-binding gas.

In some implementations of the example silicon carbide crystal growth sublimation system, the outer chamber includes a halide- or sulfur-containing gas.

In some implementations of the example silicon carbide crystal growth sublimation system, the crucible contains methane.

In some implementations of the example silicon carbide crystal growth sublimation system, the outer chamber includes an inert gas.

In some implementations, the example silicon carbide crystal growth sublimation system further comprises an insulation material at least partially surrounding the crucible and within the outer chamber.

In some implementations, the example silicon carbide crystal growth sublimation system further comprises a heater at least partially surrounding the crucible and within the outer chamber.

In some implementations of the example silicon carbide crystal growth sublimation system, the heater includes a resistive heating coil.

In some implementations, the example silicon carbide crystal growth sublimation system further comprises a heater at least partially surrounding the outer enclosure.

In some implementations of the example silicon carbide crystal growth sublimation system, the heater includes an RF heating coil.

In some implementations of the example silicon carbide crystal growth sublimation system, the outer enclosure includes quartz.

In some implementations, the example silicon carbide crystal growth sublimation system further comprises a barrel at least partially surrounding the crucible and between the crucible and the outer enclosure.

In some implementations of the example silicon carbide crystal growth sublimation system, the crucible has a higher gas permeability than the barrel.

In some implementations of the example silicon carbide crystal growth sublimation system, the barrel includes graphite.

In some implementations of the example silicon carbide crystal growth sublimation system, the graphite is coated with a polymer resin or glassy carbon.

In some implementations of the example silicon carbide crystal growth sublimation system, the graphite includes pores filled with a polymer resin or glassy carbon.

In some implementations of the example silicon carbide crystal growth sublimation system, the barrel includes a composition containing the graphite and tantalum or hafnium carbide.

In some implementations, the example silicon carbide crystal growth sublimation system further comprises an intermediate chamber between the crucible and the barrel.

In some implementations of the example silicon carbide crystal growth sublimation system, the crucible includes a gas outlet.

In some implementations, the example silicon carbide crystal growth sublimation system further comprises a gas trap between the gas outlet and the intermediate chamber.

In some implementations, the example silicon carbide crystal growth sublimation system further comprises a gas inlet configured to introduce a gas to the intermediate chamber.

In some implementations of the example silicon carbide crystal growth sublimation system, the gas inlet is fluidly connected to a dopant gas source.

In some implementations of the example silicon carbide crystal growth sublimation system, at least a portion of the gas inlet at least partially surrounds at least a portion of the gas outlet.

In some implementations of the example silicon carbide crystal growth sublimation system, the crucible and the barrel are configured to be movable along at least one axis with respect to the outer enclosure.

In some implementations of the example silicon carbide crystal growth sublimation system, a portion of the barrel is attached to a portion of the outer enclosure.

In some implementations of the example silicon carbide crystal growth sublimation system, the crucible is configured to be movable along at least one axis with respect to the barrel and the outer enclosure.

In some implementations, the example silicon carbide crystal growth sublimation system further comprises a pump configured to pump gas from the crucible.

In some implementations, the example silicon carbide crystal growth sublimation system further comprises a silicon carbide source material within the crucible.

In some implementations, the example silicon carbide crystal growth sublimation system further comprises a silicon carbide seed crystal within the crucible.

In some implementations, the example silicon carbide crystal growth sublimation system further comprises a gas inlet configured to introduce a gas to the outer chamber.

In some implementations of the example silicon carbide crystal growth sublimation system, the gas inlet is fluidly connected to a pump.

In some implementations, the example silicon carbide crystal growth sublimation system further comprises a gas outlet configured to transport gas from the crucible.

In some implementations of the example silicon carbide crystal growth sublimation system, the gas outlet is fluidly connected to a pump.

In an aspect, the present disclosure provides an example silicon carbide crystal growth sublimation apparatus. The apparatus comprises an outer enclosure, a crucible within the outer enclosure, an outer chamber between the crucible and the outer enclosure, and a barrel comprising graphite at least partially surrounding the crucible and between the crucible and the outer enclosure.

In some implementations, the example silicon carbide crystal growth sublimation apparatus further comprises an insulation material at least partially surrounding the crucible and within the outer chamber.

In some implementations, the example silicon carbide crystal growth sublimation apparatus further comprises a heater at least partially surrounding the crucible and within the outer chamber.

In some implementations of the example silicon carbide crystal growth sublimation apparatus, the heater includes a resistive heating coil.

In some implementations, the example silicon carbide crystal growth sublimation apparatus further comprises a heater at least partially surrounding the outer enclosure.

In some implementations of the example silicon carbide crystal growth sublimation apparatus, the heater includes an RF heating coil.

In some implementations of the example silicon carbide crystal growth sublimation apparatus, the outer enclosure includes quartz.

In some implementations of the example silicon carbide crystal growth sublimation apparatus, the crucible has a higher gas permeability than the barrel.

In some implementations of the example silicon carbide crystal growth sublimation apparatus, the graphite is coated with a polymer resin or glassy carbon.

In some implementations of the example silicon carbide crystal growth sublimation apparatus, the graphite includes pores filled with a polymer resin or glassy carbon.

In some implementations of the example silicon carbide crystal growth sublimation apparatus, the barrel includes a composition containing the graphite and tantalum or hafnium carbide.

In some implementations of the example silicon carbide crystal growth sublimation apparatus, the crucible includes a gas outlet.

In some implementations, the example silicon carbide crystal growth sublimation apparatus further comprises a gas trap between the gas outlet and the barrel.

In some implementations, the example silicon carbide crystal growth sublimation apparatus further comprises a gas inlet configured to introduce a gas to an intermediate chamber between the crucible and the barrel.

In some implementations of the example silicon carbide crystal growth sublimation apparatus, the gas inlet is fluidly connected to a dopant gas source.

In some implementations of the example silicon carbide crystal growth sublimation apparatus, at least a portion of the gas inlet at least partially surrounds at least a portion of the gas outlet.

In some implementations of the example silicon carbide crystal growth sublimation apparatus, the crucible and the barrel are configured to be movable along at least one axis with respect to the outer enclosure.

In some implementations of the example silicon carbide crystal growth sublimation apparatus, a portion of the barrel is attached to a portion of the outer enclosure.

In some implementations of the example silicon carbide crystal growth sublimation apparatus, the crucible is configured to be movable along at least one axis with respect to the barrel and the outer enclosure.

In some implementations, the example silicon carbide crystal growth sublimation apparatus further comprises a pump configured to pump gas from the crucible.

In some implementations, the example silicon carbide crystal growth sublimation apparatus further comprises a silicon carbide source material within the crucible.

In some implementations, the example silicon carbide crystal growth sublimation apparatus further comprises a silicon carbide seed crystal within the crucible.

In some implementations, the example silicon carbide crystal growth sublimation apparatus further comprises a gas inlet configured to introduce a gas to the outer chamber.

In some implementations of the example silicon carbide crystal growth sublimation apparatus, the gas inlet is fluidly connected to a pump.

In some implementations, the example silicon carbide crystal growth sublimation apparatus further comprises a gas outlet configured to transport gas from the crucible.

In some implementations of the example silicon carbide crystal growth sublimation apparatus, the gas outlet is fluidly connected to a pump.

In an aspect, the present disclosure provides an example method of growing a single-crystal of silicon carbide (SiC crystal) using a physical vapor transport (PVT) process in a sublimation system. The method comprises placing a source material containing silicon carbide in a reaction crucible and heating the sublimation system to a temperature of at least 1800°C. The sublimation system comprises an outer enclosure, a crucible within the outer enclosure, and an outer chamber between the crucible and the outer enclosure. A pressure within the crucible is less than a pressure within the outer chamber.

In some implementations, the example method further comprises introducing a carbon-containing gas to the outer chamber.

In some implementations of the example method, the carbon-containing gas includes methane.

In some implementations, the example method further comprises introducing a silicon-, oxygen-, or hydrogen-binding gas to the outer chamber.

In some implementations, the example method further comprises introducing a halide- or sulfur-containing gas to the outer chamber.

In some implementations, the example method further comprises introducing methane to the crucible.

In some implementations of the example method, the system includes an insulation material at least partially surrounding the crucible and within the outer chamber.

In some implementations of the example method, the system includes a heater at least partially surrounding the crucible and within the outer chamber.

In some implementations of the example method, the heater includes a resistive heating coil.

In some implementations of the example method, the system includes a heater at least partially surrounding the outer enclosure.

In some implementations of the example method, the heater includes an RF heating coil.

In some implementations of the example method, the outer enclosure comprises quartz.

In some implementations of the example method, the system includes a barrel at least partially surrounding the crucible and between the crucible and the outer enclosure.

In some implementations of the example method, the crucible has a higher gas permeability than the barrel.

In some implementations of the example method, the barrel includes graphite.

In some implementations of the example method, the graphite is coated with a polymer resin or glassy carbon.

In some implementations of the example method, the graphite includes pores filled with a polymer resin or glassy carbon.

In some implementations of the example method, the barrel includes a composition containing the graphite and tantalum or hafnium carbide.

In some implementations of the example method, the system further includes an intermediate chamber between the crucible and the barrel.

In some implementations of the example method, the crucible includes a gas outlet.

In some implementations of the example method, the system further includes a gas trap between the gas outlet and the intermediate chamber.

In some implementations of the example method, the system further includes a gas inlet fluidly connected to the intermediate chamber.

In some implementations, the example method further comprises introducing a dopant gas to the intermediate chamber through the gas inlet.

In some implementations of the example method, at least a portion of the gas inlet at least partially surrounds at least a portion of the gas outlet.

In some implementations of the example method, the crucible and the barrel are configured to be movable along at least one axis with respect to the outer enclosure.

In some implementations of the example method, a portion of the barrel is attached to a portion of the outer enclosure.

In some implementations of the example method, the crucible is configured to be movable along at least one axis with respect to the barrel and the outer enclosure.

In some implementations, the example method further comprises pumping gas from the crucible.

In some implementations of the example method, the system further includes a silicon carbide seed crystal within the crucible.

In some implementations, the example method further comprises pumping a gas to the outer chamber.

In an aspect, the present disclosure provides an example silicon carbide crystal growth sublimation system. The system comprises an outer enclosure, a crucible within the outer enclosure, an outer chamber between the crucible and the outer enclosure, a first pumping system fluidly connected to a crystal growth chamber within the crucible, and a second pumping system fluidly connected to the outer chamber.

In some implementations of the example silicon carbide crystal growth sublimation system, the first pumping system includes a gas outlet fluidly connected to the crystal growth chamber.

In some implementations of the example silicon carbide crystal growth sublimation system, the second pumping system includes a gas inlet fluidly connected to the outer chamber.

In some implementations, the example silicon carbide crystal growth sublimation system further comprises a barrel at least partially surrounding the crucible and between the crucible and the outer enclosure.

In some implementations of the example silicon carbide crystal growth sublimation system, the crucible has a higher gas permeability than the barrel.

In some implementations of the example silicon carbide crystal growth sublimation system, the barrel includes graphite.

In some implementations of the example silicon carbide crystal growth sublimation system, the graphite is coated with a polymer resin or glassy carbon.

In some implementations of the example silicon carbide crystal growth sublimation system, the graphite includes pores filled with a polymer resin or glassy carbon.

In some implementations of the example silicon carbide crystal growth sublimation system, the barrel includes a composition comprising the graphite and tantalum or hafnium carbide.

In some implementations, the example silicon carbide crystal growth sublimation system further comprises an intermediate chamber between the crucible and the barrel.

In some implementations of the example silicon carbide crystal growth sublimation system, the first pumping system includes a gas inlet fluidly connected to the intermediate chamber.

In some implementations of the example silicon carbide crystal growth sublimation system, the second pumping system includes a gas outlet fluidly connected to the outer chamber.

In some implementations of the example silicon carbide crystal growth sublimation system, the first and second pumping systems are configured to maintain a pressure within the outer chamber higher than a pressure within the crucible during a carbide crystal growth sublimation process.

In some implementations of the example silicon carbide crystal growth sublimation system, the first and second pumping systems are configured to control a gas composition within the outer chamber separately from a gas composition within the crucible.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A silicon carbide crystal growth sublimation system comprising:
an outer enclosure;
a crucible within the outer enclosure; and
an outer chamber between the crucible and the outer enclosure;
wherein the system is configured such that during a sublimation process a pressure within the crucible is less than a pressure within the outer chamber.

2. The silicon carbide crystal growth sublimation system of claim 1, further comprising an insulation material at least partially surrounding the crucible and within the outer chamber.

3. The silicon carbide crystal growth sublimation system of claim 1, further comprising a heater at least partially surrounding the crucible and within the outer chamber.

4. The silicon carbide crystal growth sublimation system of claim 1, further comprising a heater at least partially surrounding the outer enclosure.

5. The silicon carbide crystal growth sublimation system of claim 1, further comprising a barrel at least partially surrounding the crucible and between the crucible and the outer enclosure.

6. The silicon carbide crystal growth sublimation system of claim 5, wherein the crucible has a higher gas permeability than the barrel.

7. The silicon carbide crystal growth sublimation system of claim 5, wherein the barrel comprises graphite.

8. The silicon carbide crystal growth sublimation system of claim 7, wherein the graphite is coated with a polymer resin or glassy carbon and/or comprises pores filled with a polymer resin or glassy carbon.

9. The silicon carbide crystal growth sublimation system of claim 7, wherein the barrel comprises a composition comprising the graphite and tantalum or hafnium carbide.

10. The silicon carbide crystal growth sublimation system of claim 5, further comprising an intermediate chamber between the crucible and the barrel.

11. The silicon carbide crystal growth sublimation system of claim 10, wherein the crucible comprises a gas outlet.

12. The silicon carbide crystal growth sublimation system of claim 11, further comprising a gas trap between the gas outlet and the intermediate chamber.

13. The silicon carbide crystal growth sublimation system of claim 11, further comprising a gas inlet configured to introduce a gas to the intermediate chamber.

14. The silicon carbide crystal growth sublimation system of claim 13, wherein the gas inlet is fluidly connected to a dopant gas source.

15. The silicon carbide crystal growth sublimation system of claim 13, wherein at least a portion of the gas inlet at least partially surrounds at least a portion of the gas outlet.

16. The silicon carbide crystal growth sublimation system of claim 1, further comprising a pump configured to pump gas from the crucible.

17. The silicon carbide crystal growth sublimation system of claim 1, further comprising a silicon carbide source material within the crucible.

18. The silicon carbide crystal growth sublimation system of claim 1, further comprising a gas inlet configured to introduce a gas to the outer chamber.

19. A silicon carbide crystal growth sublimation system comprising:
an outer enclosure;
a crucible within the outer enclosure; and
an outer chamber between the crucible and the outer enclosure;
wherein the system is configured such that during a sublimation process the outer chamber is essentially free of silicon-containing vapor.

20. A silicon carbide crystal growth sublimation system comprising:
an outer enclosure;
a crucible within the outer enclosure;
an outer chamber between the crucible and the outer enclosure;
a first pumping system fluidly connected to a crystal growth chamber within the crucible; and
a second pumping system fluidly connected to the outer chamber.
